(19) United States
(12) Patent Application Publication
(10) Pub. No.: US 2025/0336862 A1
(43) Pub. Date: Oct. 30, 2025

(54) ELECTRONIC DEVICE AND MANUFACTURING METHOD OF ELECTRONIC DEVICE

(71) Applicant: 3DMMIC LLC., Taoyuan City (TW)

(72) Inventor: Chin-Chi Chang, Taoyuan City (TW)

(73) Assignee: 3DMMIC LLC., Taoyuan City (TW)

(21) Appl. No.: 19/031,116

(22) Filed: Jan. 17, 2025

Related U.S. Application Data
(60) Provisional application No. 63/640,216, filed on Apr. 30, 2024.

(51) Int. Cl. H01L 23/00; H01L 21/48; H01L 23/367; H01L 23/522; H01L 25/16; H10D 80/20

(52) U.S. Cl. CPC H01L 24/08; H01L 21/486; H01L 21/4875; H01L 23/3677; H01L 23/5226; H01L 24/03; H01L 24/80; H01L 24/96; H01L 24/97; H01L 25/16; H01L 2224/0384; H01L 2224/08145; H01L 2224/80895; H01L 2224/80896; H01L 2224/96; H01L 2224/97; H01L 2924/13064; H10D 80/251

(57) ABSTRACT

An electronic device and a manufacturing method thereof are provided. The manufacturing method includes: providing a first portion, where the first portion includes a first substrate, active devices formed by a semiconductor epitaxial structure grown on the first substrate, and a first bonding structure formed over the first substrate and electrically coupled to the active devices; providing a second portion, where the second portion is free of active devices and the second portion includes a second substrate, passive devices formed over the second substrate, and a second bonding structure electrically coupled to the passive devices; and forming a signal processing circuit by bonding the first portion to the second portion, where the active devices are electrically coupled to the passive devices by bonding the first bonding structure to the second bonding structure to form the signal processing circuit.

### CROSS-REFERENCE TO RELATED APPLICATION

This application claims the priority benefit of U.S. provisional application Ser. No. 63/640,216, filed on Apr. 30, 2024. The entirety of the above-mentioned patent application is hereby incorporated by reference herein and made a part of this specification.

### BACKGROUND

### Technical Field

The present disclosure relates to an electronic device and a manufacturing method thereof, and more specifically relates to an integrated microelectronic device and a manufacturing method thereof.

### Description of Related Art

With the rapid development of the wireless communication standard, communication devices (e.g., smartphones, tablets, etc.) evolve frequently to meet users' requirements. The communication devices are required to have smaller sizes, faster processing speed, and lower prices at the same time. Shrinking the sizes of electronic components may help reduce the dimensions of the wireless communication devices.

Earlier generation of the integrated circuits (ICs) adopted discrete lumped active and passive components and integrated these components on a circuit substrate (e.g., a printed circuit board (PCB)). These active and passive components are electrically connected to the circuit substrate through wire bonding or surface mounting techniques. The circuit substrate with the components mounted thereon is then processed to form a packaged device. The packaged device may operate at (or beyond) the microwave frequency range. This type of integrated circuit is called a microwave integrated circuit (MIC).

As the communication standard advances, the frequency spectrum becomes higher. The MIC employing discrete components is no longer suitable for IC implementation due to the difficulty of implementing and handling those discrete components at higher frequencies. Instead, monolithic microwave integrated circuit (MMIC) is an alternative method for semiconductor circuit integration. In a MMIC, active and passive devices are integrated monolithically, i.e., formed directly on a common semiconductor substrate.

The MMIC may be fabricated from semiconductor epitaxial layers grown on a high-quality substrate material (e.g., gallium arsenide (GaAs)). In the MMIC, active and passive devices are arranged side-by-side in a planar fashion and do not overlap in a thickness direction of the MMIC. The layout design of the active device(s) and the passive device(s) is unproductive and wasteful. For example, the active devices formed from the semiconductor epitaxial layers take only a small portion of the semiconductor epitaxial layers with the rest being etched off and wasted, and the passive devices are later formed in those areas.

### SUMMARY

The disclosure provides a manufacturing method of an electronic device includes at least the following steps. A first portion is formed, where the first portion includes a first substrate, active devices formed by an epitaxial structure grown on the first substrate, and a first bonding structure formed over the first substrate and electrically coupled to the active devices. A second portion is formed, where the second portion includes a second substrate, passive devices formed over the second substrate, and a second bonding structure electrically coupled to the passive devices. A signal processing circuit is formed by bonding the first portion to the second portion, where the active devices are electrically coupled to the passive devices by bonding the first bonding structure to the second bonding structure to form the signal processing circuit.

The disclosure also provides an electronic device, manufactured by the manufacturing method described above.

Based on the above, the present disclosure provides a novel method of forming an electronic device and structures thereof, where the first portion and the second portion are individually and independently fabricated and then bonded together to form a signal processing circuit of an electronic device. The signal processing circuit may be a microwave monolithic integrated circuit (MMIC). As the active devices, as part of MMIC, are formed in the first portion separately and independently from almost all (or a majority, e.g., more than about 80%) of the passive devices that are formed in the second portion as part of the MMIC, varying choices of materials and different processing parameters and techniques may be employed, leading to flexible design choices and more accommodating process windows. In accordance with the embodiments of the manufacturing method, the separate and independent fabrication of the active devices and passive devices enables the construction of the passive devices in better quality and higher performance, and also benefits the layout designs of the integrated circuits. In some embodiments, following the manufacturing method of this disclosure, the passive devices may be stacked over the active devices along the thickness direction, resulting in a smaller footprint for the circuit.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIGS. 1A-1E are schematic cross-sectional views illustrating a manufacturing method of an active device wafer, according to some embodiments of the disclosure.

FIG. 1F is a schematic view illustrating an exemplary layout of various structures at different levels of the active device wafer in accordance with some embodiments.

FIG. 2 is a schematic cross-sectional view illustrating a passive device wafer, according to some embodiments.

FIGS. 3A-3G are schematic cross-sectional views illustrating a manufacturing method of an electronic device with a frontside to frontside configuration, according to some embodiments.

FIG. 4 is a circuit diagram of the electronic device of FIG. 3G, according to some embodiments.

FIG. 5 is a schematic cross-sectional view of an electronic device, according to alternative embodiments.

FIGS. 6A-6E are schematic cross-sectional views illustrating a manufacturing method of an electronic device with a frontside to backside configuration, according to some embodiments.

FIG. 7 is a schematic cross-sectional view of an electronic device, according to alternative embodiments.

FIGS. 8A-8E are schematic cross-sectional views illustrating another manufacturing method of an electronic device with a frontside to frontside configuration, according to some embodiments.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

Embodiments of the present disclosure provide novel methods of forming an electronic device and structures thereof. The present disclosure provides a more efficient fabrication approach of MMIC, where an active device wafer and a passive device wafer are separately fabricated and then bonded together to form electronic devices. For example, the respective electronic device is a microwave monolithic integrated circuit (MMIC) die. Unlike some MMIC having passive devices and active devices formed all together from the same single semiconductor wafer, the fabrication approach of the present disclosure focuses on forming substantially all the active devices needed for the MMIC from an active device wafer, and forming substantially all (or a majority, e.g., more than about 80%) of the passive devices needed for the MMIC from a passive device wafer. In accordance with embodiments of this disclosure, the active device wafer and the passive device wafer are manufactured separately but are co-designed and vertically integrated to form a complete signal processing circuit. Either the active device wafer or the passive device wafer may be considered as a work-in-process or a work-in-process unit, a part of the signal processing circuit. Through such vertical integration, the die size or the footprint of the signal processing circuit is largely reduced in the horizontal plane, leading to die size shrinkage. In addition, because the fabrication of the active devices is separate and independent from the fabrication of the passive devices, the processing methods and conditions for forming the passive devices are not limited by the stringent requirements of the processing techniques for fabricating the active devices, flexible choices of processing techniques and larger process windows are provided, which simplifies manufacturing and enhances overall device performance and reliability.

In accordance with embodiments of the present disclosure, the manufacturing method allows the active devices to be fabricated on a wafer with higher costs while the passive devices are fabricated on a lower-cost wafer, resulting in higher production yields and more economical production costs. Furthermore, the passive devices, as part of the integrated circuit, can be made on substrates with lower dielectric loss, low signal loss or higher quality factor (Q-factor), while the active devices, as part of the integrated circuit, may be fabricated on substrates offering better electron mobility or higher breakdown voltage. Since the fabrication of the active devices is separate and independent from the fabrication of most of the passive devices, instead of being limited by employing processing techniques suitable for both of the active and passive devices, either the active devices or the passive devices may be respectively fabricated through the most suitable processing techniques and conditions, which enables the performance characteristics to be individually optimized for different types of devices.

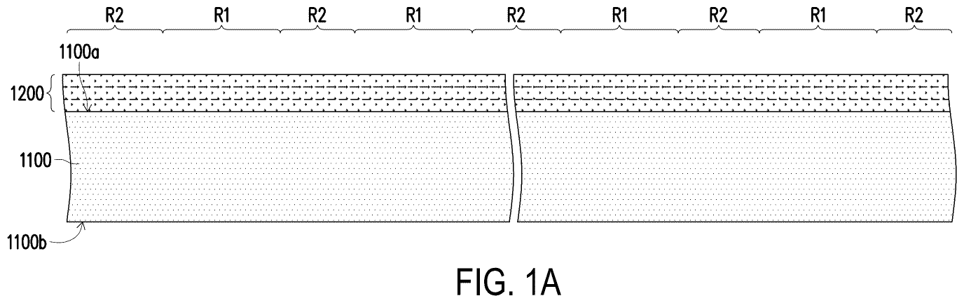

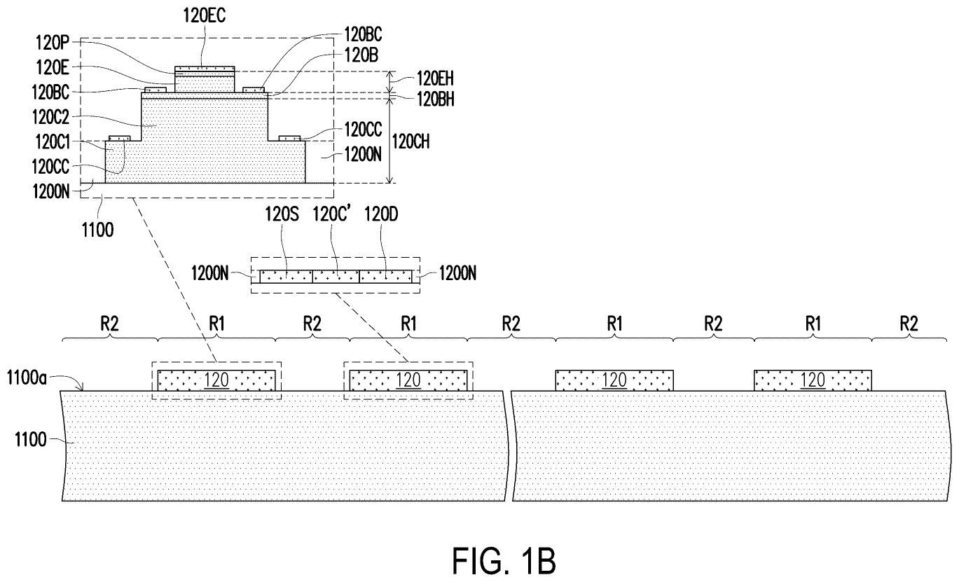

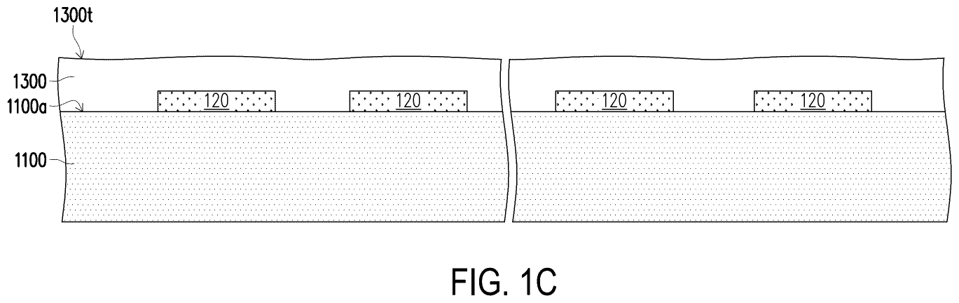

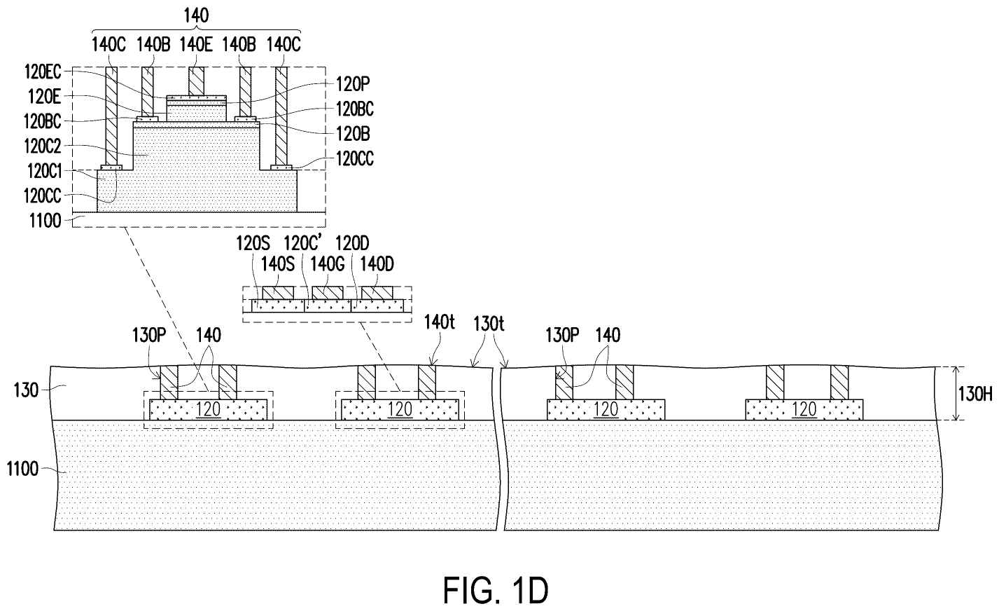

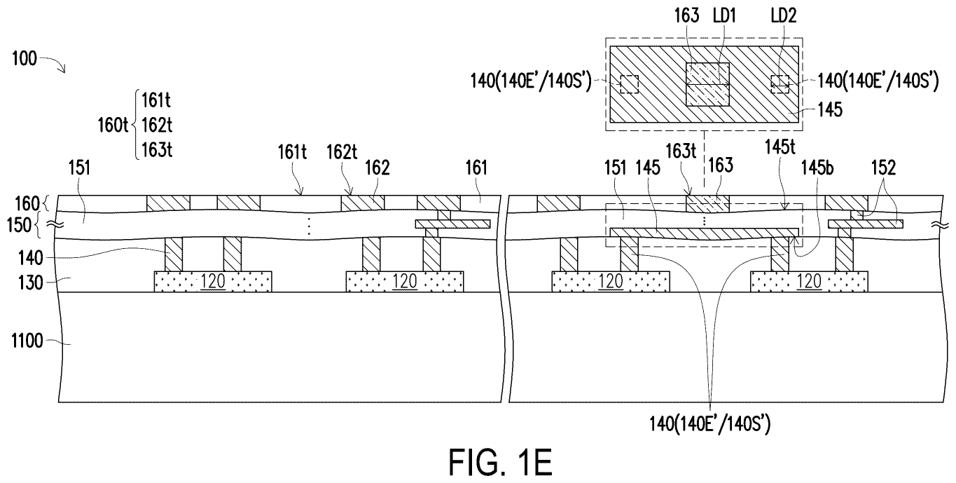

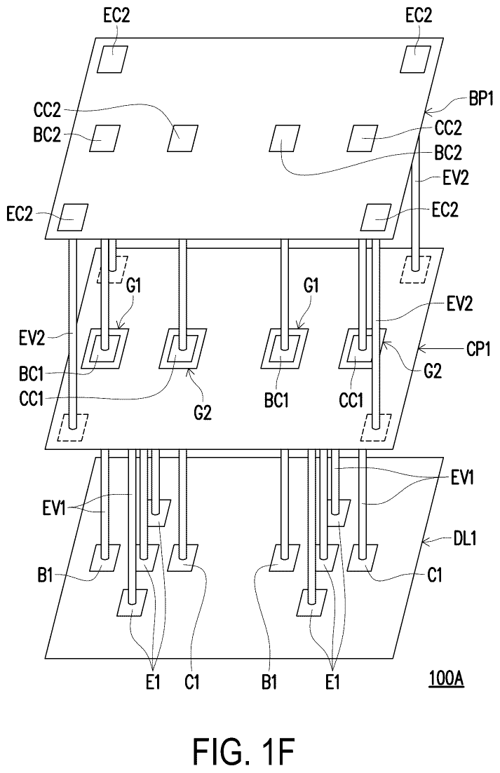

FIGS. 1A-1E are schematic cross-sectional views illustrating a manufacturing method of an active device wafer 100, according to some embodiments. Referring to FIG. 1A, a semiconductor epitaxial structure 1200 may be formed on a first substrate 1100. The first substrate 1100 may include a first side (or an active side) 1100a and a second side (or a backside) 1100b opposite to the first side 1100a. The first substrate 1100 may include one or more semiconductor material(s) such as a compound semiconductor including gallium arsenic (GaAs), gallium nitride (GaN), silicon carbide (SiC), indium phosphide (InP), other suitable compound semiconductor, element semiconductor (e.g., silicon (Si), germanium (Ge), etc.), the like, a combination thereof (e.g., GaN-on-SiC, SiGe, or the like), etc. In some other embodiments, the first substrate 1100 further includes non-semiconductor material(s) such as glass, sapphire, and/or the like. Other suitable substrate having higher quality material for providing good performance of devices may be used.

In some embodiments, one or more epitaxial process(es) may be performed on the first side 1100a of the first substrate 1100 to form the semiconductor epitaxial structure 1200. The semiconductor epitaxial structure 1200 may include one or more semiconductor epitaxial layer(s). The epitaxial processes may be or include metal-organic chemical vapor deposition (MOCVD), molecular beam epitaxy (MBE), or other suitable epitaxially growth techniques. By optimizing the epitaxial design parameters, the size of the subsequently-formed active devices may be reduced. In some embodiments, one or more doping process(es) may be performed on the semiconductor epitaxial structure 1200. In some embodiments where the first substrate 1100 includes non-semiconductor material(s) such as glass, sapphire, or the like, when growing the semiconductor epitaxial structure 1200 on the first substrate 1100, appropriate surface treatments, specialized buffer layer designs, and precise temperature control during processing are required. The selection and the design of these processes and techniques may vary based on different application requirements and the designs for the semiconductor epitaxial structure 1200.

The semiconductor epitaxial structure 1200 may include active areas (or active regions) R1 and sacrificial areas (or sacrificial regions) R2 neighboring the active areas R1, where the semiconductor epitaxial structure 1200 in the active areas R1 may be used for the subsequently-formed active devices, while the semiconductor epitaxial structure 1200 in the sacrificial areas R2 may be removed or neutralized for electrical isolation purposes. In some embodiments, the semiconductor epitaxial structure 1200 includes a plurality of semiconductor epitaxial layers stacked upon one another. Some of the semiconductor epitaxial layers may be doped with dopants and the other semiconductor epitaxial layers may be undoped. For example, the semiconductor epitaxial layer(s) doped with a p-type dopant and the semiconductor epitaxial layer(s) doped with an n-type dopant are alternately stacked. In some embodiments, the semiconductor epitaxial structure 1200 includes a semiconductor epitaxial layer having a plurality of doped regions. For example, a portion of the regions is doped with a p-type dopant and the other portion of the regions is doped with an n-type dopant. The dashed lines illustrated inside the semiconductor epitaxial structure 1200 indicate that the semiconductor epitaxial structure 1200 may include one or more semiconductor epitaxial layers. It is noted that the number and the thickness of the semiconductor epitaxial layer(s) 1200 depend on the types of the subsequently-formed active devices and construe no limitation in the disclosure.

Referring to FIG. 1B and FIG. 1A, a portion of the semiconductor epitaxial structure 1200 may be patterned to form a plurality of active devices 120, while the other portion of the semiconductor epitaxial structure 1200 may be removed (or neutralized). For example, by performing one or more etching processes, the semiconductor epitaxial structure 1200 in the active areas R1 is etched or patterned to form the respective active device 120 (with corresponding profiles or configurations). The active devices 120 may be or include transistors such as bipolar transistors (e.g., heterojunction bipolar transistors (HBTs), bipolar junction transistors (BJTs), etc.), field effect transistors (FETs) (e.g., high electron mobility transistors (HEMTs)), diodes, the like, a combination thereof, etc. The other portions of the semiconductor epitaxial structure 1200 in the sacrificial areas R2 may be removed by one or more etching process(es) and/or neutralized through one or more ion bombardment processes.

In some embodiments, referring to the exemplary expanded view shown at the upper part of FIG. 1B where HBT as an exemplary active device, the respective active device 120 includes a sub-collector layer 120C1, a collector layer 120C2, a base layer 120B overlying the collector layer 120C2, an emitter layer 120E overlying the base layer 120B, and a cap layer 120P overlying the emitter layer 120E, where the sub-collector layer 120C1, the collector layer 120C2, the base layer 120B, the emitter layer 120E, and the cap layer 120P are operably coupled as an HBT. As shown in FIG. 1B, the active device 120 implemented as the HBT may have a stepped profile. Such stepped profile may cause the top surface of the subsequently-formed dielectric layer (1300 in FIG. 1C) to be uneven. In some embodiments, the base layer 120B is made of p-type doped material, the emitter layer 120E is made of n-type doped material, and the cap layer 120P is made of n-type doped material. For example, the thickness 120EH of the combination of the emitter layer 120E and the cap layer 120P is in a range of about 50 nanometers and 300 nanometers, and the thickness 120BH of the base layer 120B is in a range of about 30 nanometers and 100 nanometers. The base layer 120B may be thinner than the thickness 120EH and the collector layer 120C2. For example, the sub-collector layer 120C1 is n-type doped material, and the collector layer 120C2 is made of n-type doped material. The collector layer 120C2 may be formed by using gradient doping technology, and the collector layer 120C2 has a doping concentration lower than that of the sub-collector layer 120C1. For example, the total thickness 120CH of the collector layer 120C2 and the sub-collector layer 120C1 is in a range of about 1000 nanometers and 3500 nanometers, and the collector layer 120C2 may be thicker than the sub-collector layer 120C1. It should be noted that the ranges of the thicknesses provided herein are merely exemplary and may vary depending on product and design requirements.

In some embodiments, a neutralized epitaxial structure 1200N in the sacrificial areas R2 laterally surrounds the sub-collector layer 120C1. Alternatively, the portions of the semiconductor epitaxial structure in the sacrificial areas R2 are neutralized (or etched off). Therefore, the neutralized epitaxial structure 1200N is shown in dashed lines to indicate the non-functionality or non-existence.

In some embodiments, the contacts, including 120CC, 120BC, and 120EC, are respectively formed on the sub-collector layer 120C1, the base layer 120B, and the cap layer 120P overlying the emitter layer 120E. The contacts (e.g., 120EC, 120BC, and 120CC) may be formed during or after etching the semiconductor epitaxial structure 1200 to form the step pyramid profiles of the sub-collector layer 120C1, the collector layer 120C2, the base layer 120B, the emitter layer 120E, and the cap layer 120P. For example, the contacts including 120EC, 120BC, and 120CC may be made of one or more conductive material(s). In some embodiments, the emitter contact 120EC is formed on the top surface of the cap layer 120P, the base contacts 120BC is formed on the top surface of the base layer 120B and disposed alongside the emitter layer 120E, and the collector contacts 120CC is formed on the top surface of the sub-collector layer 120C1 and disposed alongside the collector layer 120C2.

The major applications using HBTs as the active devices 120 may include wireless communication, fiber optic communication, satellite communication, auto-motive electronics, etc. For example, the active devices 120 are implemented as HBTs with excellent high-frequency performance and may be used in power amplifier in wireless communication devices and base stations. In some embodiments, the active devices 120 are implemented as HBTs for fiber optic communication modules due to HBT's high electron mobility and excellent frequency response.

In some embodiments, the active devices 120 are implemented as HBTs for satellite communication equipment and for power amplification and signal processing due to HBT's high gain and high-frequency performance. In some embodiments, the active devices 120 are implemented as HBTs for auto-motive electronic system due to HBT's high reliability and high-power performance.

With continued reference to FIG. 1B, referring to the exemplary expanded view shown at the middle part of FIG. 1B where HEMT as an exemplary active device, in some embodiments, the respective active device 120 includes a source region 120S, a drain region 120D, and a channel region 120C′ formed between the source and drain regions (120S and 120D), where these regions and the subsequently-formed gate and S/D electrodes are operably coupled as a HEMT. The channel region 120C′ utilizes a heterostructure composed of suitable compound semiconductor material to form a high electron mobility two-dimensional electron gas (2DEG), thereby enhancing the device's high-frequency performance and electron mobility. In some embodiments, a neutralized epitaxial structure 1200N in the sacrificial areas R2 laterally surrounds the source and drain regions (120S and 120D). For example, the portions of the semiconductor epitaxial structure in the sacrificial areas R2 may be neutralized though ion implantation (or etched off). Therefore, the neutralized epitaxial structure 1200N is shown in dashed lines to indicate the non-functionality or non-existence. It should be noted that the illustration of the active devices 120 in FIG. 1B is merely examples and the active devices 120 may have a different configuration/type from those shown in the figures.

In some embodiments, a ratio of active area layout (AAL ratio), i.e., a ratio of a total surface area of the active areas R1 to a total surface area of the first side 1100a of the first substrate 1100, is about 10% or greater than about 10%, or in a range from about 10% to about 90%. The active areas (AA) may be the total surface area of the semiconductor epitaxial layer(s) for forming the active devices 120 and/or may be the total surface area of the active areas R1. For example, the AAL ratio may be about or greater than 20% or in a range from about 20% to about 50%. The ratio of the total surface area of the active areas R1 to a total surface area of the first side 1100a of the first substrate 1100, referred as the AAL ratio, may be any suitable value, such as equal to or greater than 10%, 20%, 30%, 40%, 50%, 60%, 70%, 80% and equal to or less than 90%, etc., or may be any suitable range between about 10% and about 90%, or from about 10% to about 50%. It is appreciated that for certain MMIC including active and passive devices integrated monolithically on a common substrate of a single wafer, a ratio of the total surface area of the active areas R1 to a total wafer area is usually lower than 30%, such as about 5% to 25%. In the present embodiments, the ratio of the total surface area of the active areas R1 to the total wafer area (e.g., AAL ratio) may be higher, since the total wafer area (e.g. active device wafer area) is efficiently and mainly used for forming the active devices, rather than being used for forming the passive devices. Along with the die size shrinkage, the amount of the active devices 120 per unit area can be significantly increased, and the active devices for the MMIC may be fabricated at lower costs following our fabrication approach.

Referring to FIG. 1C and FIG. 1B, a dielectric layer 1300 may be formed on the first side 1100a of the first substrate 1100 to cover the active devices 120. The dielectric layer 1300 may be thick enough to embed the active devices 120 therein. The dielectric layer 1300 may include one or more suitable dielectric material(s) such as silicon nitride, silicon oxide, polyimide, benzocyclobutene (BCB), polybenzoxazole (PBO), the like, a combination thereof, etc. The dielectric layer 1300 may be formed by any suitable deposition process (e.g., spin-coating, chemical vapor deposition (CVD), physical vapor deposition (PVD), etc.). In some embodiments, the dielectric layer 1300 has an uneven or even bumpy top surface 1300t made up of heights and valleys, where the heights correspond to the areas where the active devices 120 are formed, and the valleys correspond to the rest areas without the active devices 120.

Referring to FIG. 1D and FIG. 1C, portions of the dielectric layer 1300 may be removed to form a dielectric layer 130 with openings 130P, and then contact plugs 140 may be formed in the openings 130P and filling up the openings 130P. For example, one or more etching processes are performed on the dielectric layer 1300 to form the openings 130P, where the openings 130P expose at least a portion of the active devices 120. Next, one or more conductive material(s) may be formed in the openings 130P to form the contact plugs 140 which are in physical and electrical contact with the portion of the active devices 120 exposed by the openings 130P. A smoothing process (e.g., grinding, etching and/or rough chemical mechanical polishing (CMP)) is optionally performed on the dielectric layer 130 (and the contact plugs 140, if desired) to level or smooth the top surfaces of the dielectric layer 130 and the contact plugs 140. However, depending on the unevenness of the dielectric layer 130, it is understood the top surface 130t of the dielectric layer 130 may be fully planarized. The dielectric layer 130 may have a sufficient thickness 130H for insulation and the material of the dielectric layer 130 may be chosen to help improve the electromagnetic interference between the active devices and passive devices. Herein, vias, plugs, via plugs may be used interchangeably.

In some embodiments, referring to the exemplary expanded view shown at the upper part of FIG. 1D where HBT as the exemplary active device, the openings 130P expose portions of the collector contacts 120CC, the base contacts 120BC, and the emitter contact 120EC. The contact plugs 140 formed in the openings 130P may thus be in physical and electrical contact with the portions of the collector contacts 120CC, the base contacts 120BC, and the emitter contact 120EC to respectively form collector terminals 140C, base terminals 140B, and emitter terminals 140E.

In some embodiments, referring to the exemplary expanded view shown at the middle part of FIG. 1D where HEMT as the exemplary active device, the openings 130P expose portions of the source region 120S, the drain region 120D, and the channel region 120C′. The contact plugs 140 formed in the openings 130P may thus be in physical and electrical contact with the source region 120S, the drain region 120D, and the channel region 120C′ and respectively form source contacts 140S, drain contacts 140D, and gate electrodes 140G.

Referring to FIG. 1E and FIG. 1D, an interconnect structure 150 is formed over the dielectric layer 130, and then a bonding structure 160 is formed. In some embodiments, the bonding structure 160 formed over the dielectric layer 130 is electrically coupled to the active devices 120 through the contact plugs 140 and the interconnect structure 150. In some embodiments, the bonding structure 160 includes a bonding dielectric layer 161 and a plurality of bonding features 162 embedded in the bonding dielectric layer 161. The material of the bonding dielectric layer 161 may be different from that of the dielectric layer 130. The bonding features 162 may include one or more conductive material(s) and may be electrically coupled with the contact plugs 140. In some embodiments, the bonding features 162 are made of one or more metals, alloys or metallic materials. The respective bonding feature 162 may be or include a bonding pad, a bonding via, a metallic pad, or a combination thereof.

In some embodiments, a planarization process (e.g., CMP, grinding, etc.) is performed on the bonding structure 160 for forming a smoother and levelled surface for assisting bonding. For example, through the fine planarization process, the top surfaces 162t of the bonding features 162 and the top surface 161t of the bonding dielectric layer 161 may be substantially coplanar. In some embodiments, following the fine planarization process, one or some conductive features may be polished with top surfaces 162t being not completely planar, for example, some of the top surfaces 162t are slightly recessed or protruded from the top surface 161t. The top surfaces 162t of the bonding features 162 and the top surface 161t of the bonding dielectric layer 161 may be collectively viewed as a bonding surface 160t of the bonding structure 160 of the active device wafer 100. The bonding surface 160t may be substantially even and have higher planarity than the top surface 130t of the dielectric layer 130. For example, the bonding surface 160t exhibit better surface flatness (less deviation) and smaller surface roughness than those of the top surface 130t of the dielectric layer 130.

With continued reference to FIGS. 1E and 1D, the interconnect structure 150 is formed over the dielectric layer 130 before the formation of the bonding structure 160, and the bonding structure 160 is later formed on the interconnect structure 150. Following the formation of the interconnect structure 150 and the bonding structure 160, the active device wafer 100 is formed. For example, the interconnect structure 150 includes at least a dielectric layer 151 and metallization patterns 152 embedded in the dielectric layer 151, where the metallization patterns 152 of the interconnect structure 150 electrically couples the overlying bonding features 162 with some of the underlying contact plugs 140. It is understood that the dielectric layer 151 may include multiple dielectric sub-layers and the metallization patterns 152 may be sandwiched between adjacent dielectric sub-layers. In some embodiments, the metallization patterns 152 include conductive pads and conductive lines that may extend horizontally over the top surface 130t of the dielectric layer 130 and vertically extending vias to electrically couple adjacent active devices 120 through the contact plugs 140. In some embodiments, the metallization patterns 152 re-route the electrical signals of the active devices 120 and considered as routing wiring patterns.

With continued reference to FIGS. 1E and 1D, the bonding structure 160 may include thermally conductive features 163 (one is shown) embedded in and laterally covered by the bonding dielectric layer 161. In some embodiments, the thermally conductive feature 163 may also function as electrically conductive feature(s). The respective thermally conductive feature 163 may include a thermally conductive pad, a thermally conductive via, or a combination thereof. The thermally conductive features 163 may include the same conductive material(s) as the material of the bonding features 162. Alternatively, the thermally conductive features 163 may include one or more material(s) with higher thermal conductivity than the material(s) of the bonding features 162. The top surfaces 163t of the thermally conductive features 163 may be substantially coplanar with the top surfaces 162t of the bonding features 162 and may be included in the bonding surface 160t. In some embodiments, the top surfaces 163t of one or some of the thermally conductive features 163 are not completely planar, for example, some of the top surfaces 163t are slightly recessed or protruded from the top surface 161t. In FIG. 1E, a schematic top view of a portion of the structure circled by the lower dashed square is shown in the upper dashed square at the upper part of FIG. 1E, illustrating the relative arrangements of the thermally conductive feature 163 and contact plugs 140. It should be noted that the top-view shapes of the elements shown in FIG. 1E are merely examples and construed no limitation in the disclosure. In some embodiments, a lateral dimension LD1 of the respective thermally conductive feature 163 is greater than a lateral dimension LD2 of the respective contact plugs 140 (140E′ of the active device as HBT or 140S′ of the active device as HEMT) for better thermal dissipation. Alternatively, the lateral dimensions LD1 and LD2 may be substantially equal to each other.

With continued reference to FIGS. 1E and 1D, in some embodiments where some (or all) of the active devices 120 are implemented as HBTs, the interconnect structure 150 includes at least one conductive layer 145 formed over the common emitter terminals 140E′ of the underlying active devices 120 and thermally connected with the above thermally conductive feature(s) 163. The conductive layer 145 is thermally connected with the above thermally conductive feature 163 and the contact plug 140 (e.g. common emitter terminals 140E′) of the below active device(s) 120 for assisting heat transferring and thermal dissipation, and functions as a heat transfer bar or a part of thermal-dissipation path in the resulting device. In some embodiments, the conductive layer 145 that is electrically coupled or connected with the common emitter terminals 140E′ is electrically grounded and functions as a ground bar. For example, the conductive layer 145 is formed as a thermally conductive metallic strip or band extending horizontally on the dielectric layer 130 and conformally overlying the top surface 130t of the dielectric layer 130. In some embodiments where the dielectric layer 130 has an uneven or bumpy top surface, the bottom surface 145b, or the top surface 145t or both of the conductive layer 145 may be formed as an uneven or bumpy surface conformal to the top surface 130t of the dielectric layer 130. In some embodiments, the conductive layer 145 is formed within the interconnect structure 150 and is at the same level as any one of the metallization patterns 152 of the interconnect structure 150. It is understood that the conductive layer 145 may be thermally connected with the above thermally conductive feature 163 and the contact plug 140 for heat transfer and dissipation purposes. However, for heat transfer and dissipation purposes, the conductive layer 145 is not necessarily physically directly connected with either or both of the thermally conductive feature 163 and the contact plug 140.

Although only two contact plugs 140 (e.g. common emitter terminals 140E′) of two active devices 120 are shown in FIG. 1E, the conductive layer 145 may span across multiple contact plugs 140 (e.g. common emitter terminals 140E′) of multiple active devices 120 depending on the product requirements.

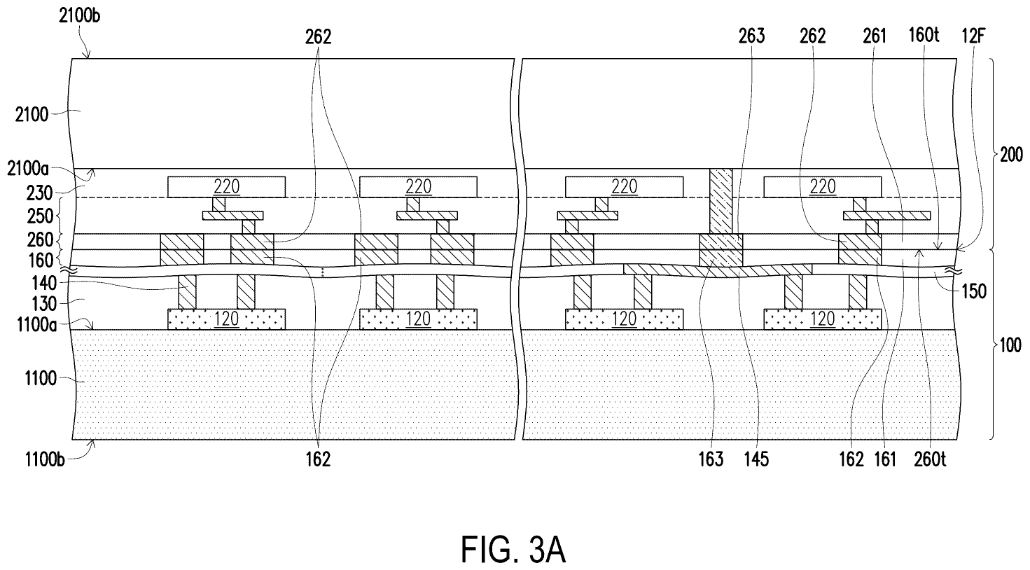

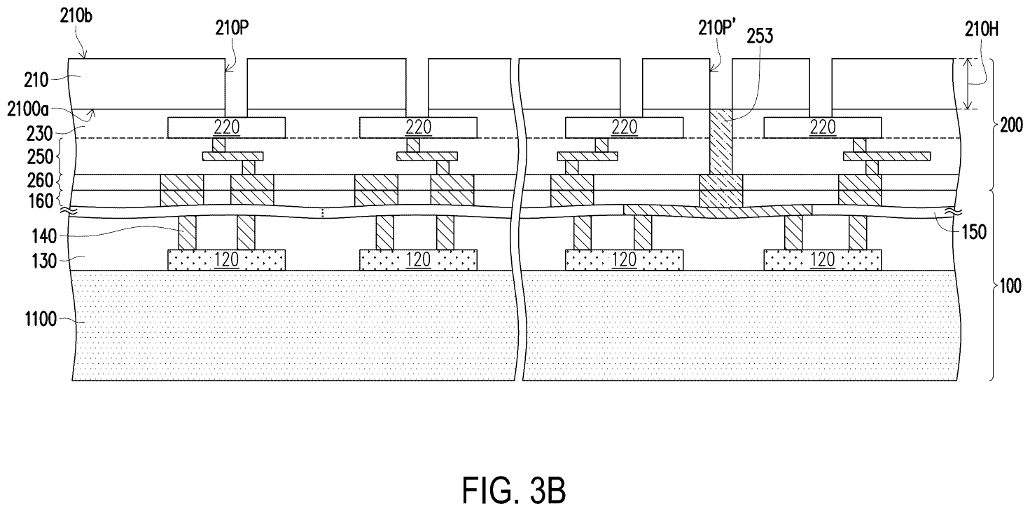

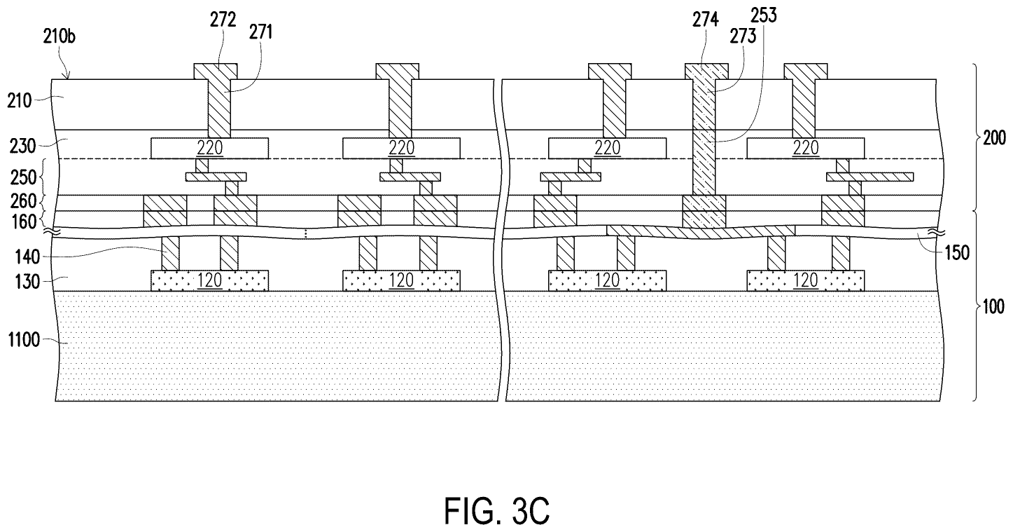

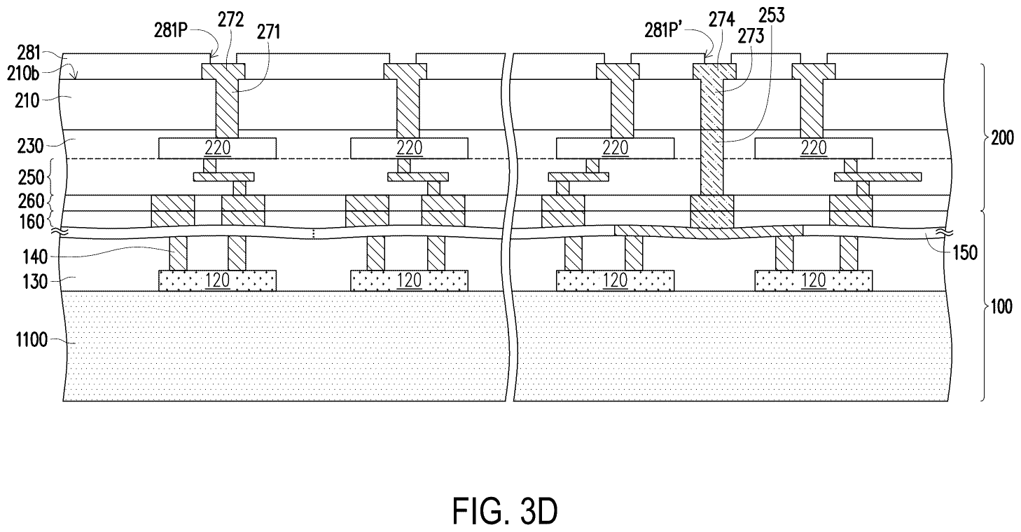

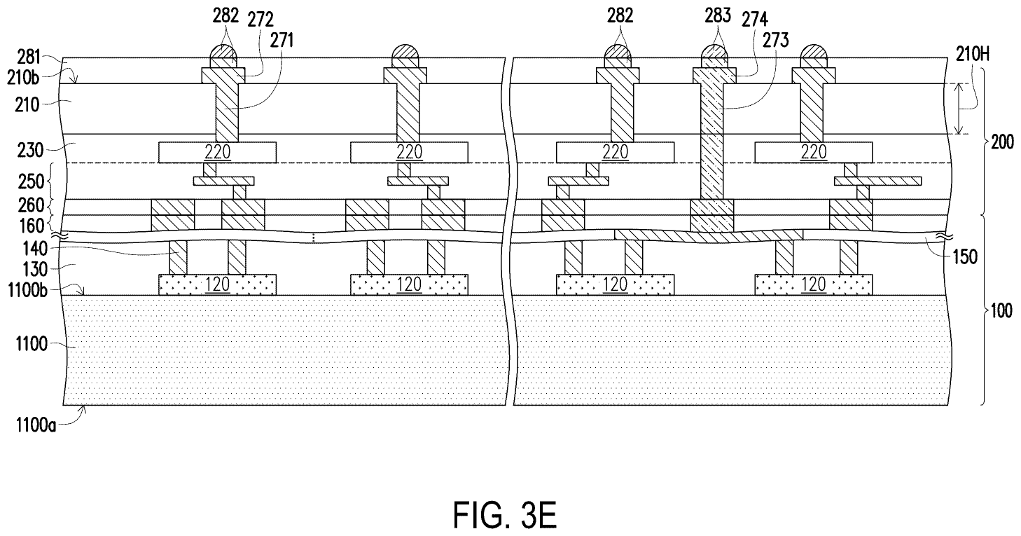

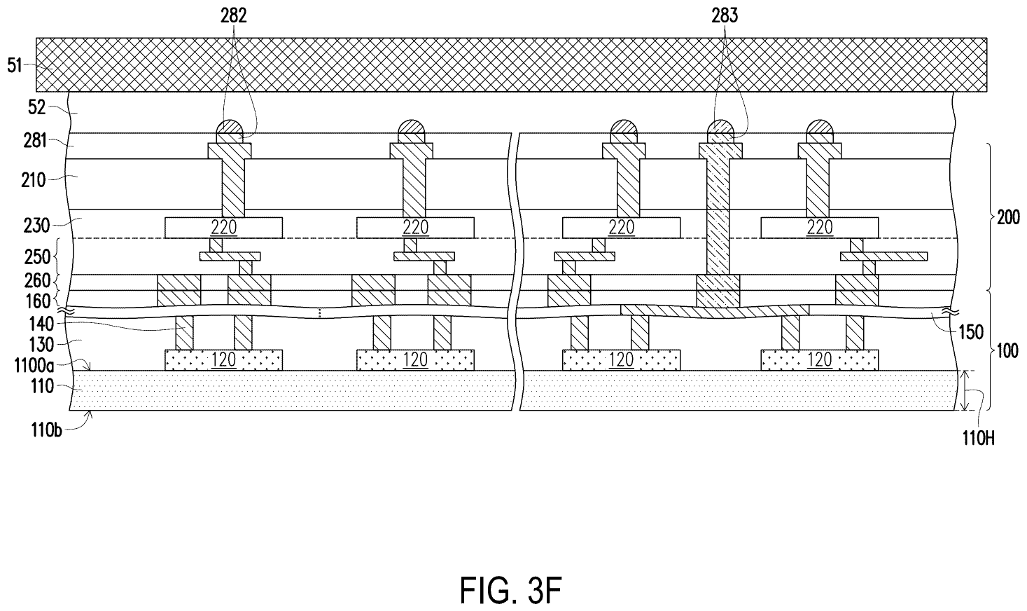

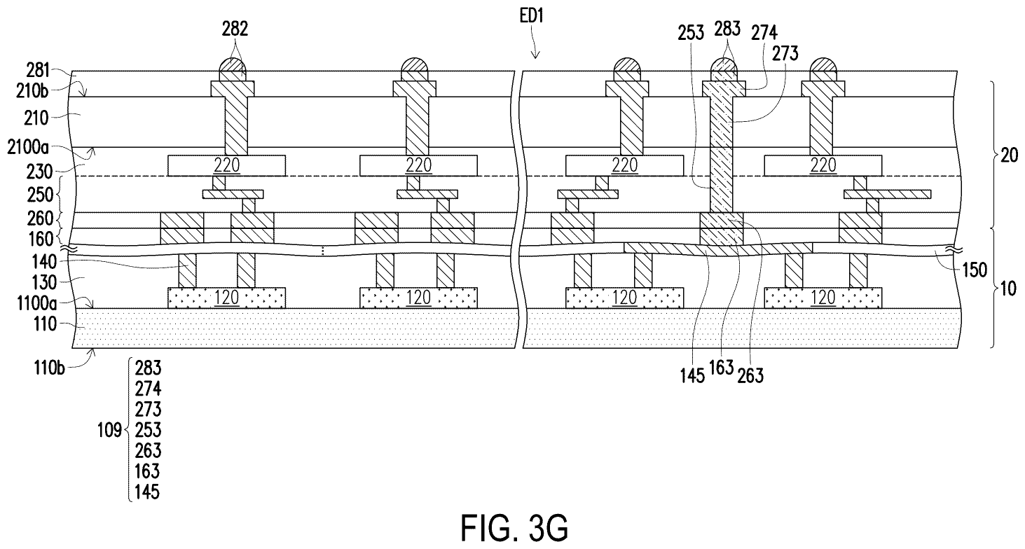

In some embodiments where some (or all) of the active devices 120 are implemented as FETs (e.g., HEMTs), the conductive layer 145 is formed over the common source terminals 140S′ of the active devices 120, and the thermally conductive feature(s) 163 may be formed over the conductive layer 145. In addition to serving as a part of the thermal-dissipation path, the conductive layer 145 and the thermally conductive feature(s) 163 may be subsequently coupled to an electrical ground pad in the fabricated device (see FIG. 3G).

The active device wafer 100 may then be prepared for the subsequently-performed bonding process (see FIG. 3A). The active device wafer 100 may be composed of the first substrate 1100, the active devices 120 epitaxially grown on the first substrate 1100, the contact plugs 140 landing on the active devices 120, the dielectric layer 130 covering the active devices 120 and the contact plugs 140, the bonding structure 160 overlying the dielectric layer 130 and the contact plugs 140, and the interconnect structure 150 between the bonding structure 160 and the contact plugs 140. In some embodiments, the active device wafer 100 is free of passive devices (e.g., inductors, capacitors, resistors, etc.). The active devices 120 and the conductive features (e.g., 140, 145, 162, and 163) coupled thereto may not be formed as functional circuits/signal processing circuits (e.g., power amplifiers, low noise amplifiers, mixers, etc. for a radio frequency (RF) application) at this stage. The active device wafer 100 may be considered as a work-in-process (WIP) unit.

In alternative embodiments, the active device wafer 100 includes the active devices 120 and passive devices (e.g., resistors, capacitors, and/or inductors) connected to the active devices 120 for certain purposes. For example, some of the active devices 120 are connected to resistors (e.g., formed by the epitaxial structure or thin film resistor) to control the current flow to these active devices such that the thermal stability can be improved. In such cases, the combination of these active devices and the resistors in the active device wafer 100 does not function as a signal processing circuit. The signal processing circuit may be formed after the active device wafer 100 is physically and electrically bonded to the passive device wafer (see FIG. 3A). Therefore, in such embodiments, the active device wafer 100 can still be considered as a WIP unit.

It is understood that the active device wafer 100 is a wafer structure comprised of multiple diced units or die units, which will be obtained after singulation performed upon the bonded structure of the active device wafer 100 with at least one passive device wafer. FIG. 1F is a schematic view illustrating the layout of various structures at different levels of the active device wafer in accordance with some embodiments of this disclosure. In FIG. 1F, one diced unit of the active device wafer 100A is shown as an exemplary portion of the active device wafer 100A, and the active device wafer 100A is substantially the same as the active device wafer 100 described in the previous contexts. Referring to FIG. 1F, in some embodiments, a device layer DL1 is shown to represent the active devices formed within the active device wafer 100A, a bonding plane BP1 is shown to represent the bonding surface or interface of the bonding structure, and a common platform CP1 is located between the device layer DL1 and the bonding structure. It is noted that the common platform CP1 is located at the level of the interconnect structure 150 (in FIG. 1E) and may be formed as part of the interconnect structure and located in the interconnect structure 150. Although only a portion of the active device wafer is shown, the common platform CP1 extends over the whole device layer (spanning over most or all of the active devices) in the diced unit and even extends over most or all of the diced units of the whole active device wafer 100A.

With reference to FIG. IF, in some embodiments, the active devices are shown as a device layer DL1 where the active devices are implemented as HBTs, the base terminals B1 and the collector terminals C1 are respectively arranged in separate zones, while the emitter terminals E1 are arranged in several separate zones beside the base terminals B1 and the collector terminals C1 and spaced apart from the base terminals B1 and the collector terminals C1. The exemplary configurations or shapes of the base terminals B1, the collector terminals C1 and the emitter terminals E1 are merely simplified and schematic and do not reflect the physical outlines, conformation or layout patterns of these elements, and the numbers or sizes of these elements shown in the drawing are not intended to limit the scope of this disclosure. In some embodiments, the common platform CP1 is formed as a metallic sheet extending within the interconnect structure 150 (e.g. extending within the dielectric layer 151 over the dielectric layer 130 and the active devices 120, see FIG. 1E) over the entire diced unit of the active device wafer. In some embodiments, the common platform CP1 functions as a macro ground plane (common ground plane) in the diced unit for all the devices in the device layer DL1. The common platform CP1 serves as a macro ground plane and minimizes the parasitic ground inductance incurring on the emitter terminal, leading to better electrical performance, especially for high frequency devices. In one embodiment, the common platform CP1 formed together with the metallization patterns is similarly made of a highly thermally conductive material (such as copper or copper alloys), and the common platform CP1 also functions as a heat dissipation sheet or a heat transfer element. Referring to FIG. 1F, the electrical connection between each emitter terminal E1 and the

common platform CP1 and between the common platform CP1 and each contact EC2 may be established through at least one vertically extending conductive plugs or metallic via plugs EV1 and EV2 respectively for establishing shorter or shortest paths of electrical connection. The dashed boxes on the common platform CP1 as shown in FIG. 1F may be considered as contact locations of the conductive plugs EV2, the common platform CP1 as a whole functions as the platform connecting and in contact with the emitter terminals E1, and the conductive plugs EV2 electrically connecting the common platform CP1 and the contacts EC2 of the emitter terminals E1. Furthermore, because all the emitters of the device layer/level are connected to the common platform which will be connected through metal connections to the ground pads/plane of the diced unit, shorter or shortest paths of metal connection between the emitters to the ground is established, minimizing the unwanted extra inductance and further improving MMIC performance. It is understood that stacked vias and optionally metallization patterns including traces/lines in the interconnect structure may also be incorporated for electrical connection.

In some embodiments, the emitter terminals E1 of all the devices in the device layer DL1 are connected to the common platform CP1, regardless the locations of the emitter terminals E1, thereby consolidating all emitter terminals onto the same common platform CP1. In some embodiments, for layout flexibility, the locations of the contacts EC2 of the emitter terminals E1 on the bonding plane BP1 are arranged in a peripheral region of the bonding plane BP1 and/or adjacent to or at the corners of the diced unit, so that the non-peripheral region (the inner middle region) of the bonding plane BP1 of the diced unit may be spared. The peripheral layout of the contacts EC2 of the emitter terminals E1 on the bonding plane BP1 leads to the correspondingly peripheral layout of the corresponding bonding pads of the passive device wafer that is bonded with the active device wafer. Accordingly, the spared inner region of the bonding plane of the active device wafer leads to the open inner region reserved for the layouts of the passive devices in the passive device wafer and/or for other auxiliary circuit elements such as elements or components for matching networks, bias circuits, protection circuits, power detection circuits, linearization circuits, temperature compensation circuits, etc.

In some embodiments, the common platform CP1 is formed with openings G1 and G2, and the locations of the openings G1, G2 may correspond to (or vertically aligned with) the locations of the common base terminal B1 and the common collector terminal C1, so that the connection between the base terminals B1 and its corresponding contacts BC1, BC2 and the connection between the collector terminals C1 and its corresponding contacts CC1, CC2 passing through the openings G1, G2 on the common platform CP1 and reaching the bonding plane BP1. The base terminals B1 and the collector terminals C1 are not electrically connected with the common platform CP1. For example, the base terminals B1 are connected with contacts BC1 formed within the opening G1 and connected with contacts BC2 formed on the bonding plane BP1, and the collector terminals C1 are connected with contacts CC1 formed within the openings G2 and connected with contacts CC2 formed on the bonding plane BP1. Such layout design of the diced unit allows the base terminals B1 and collector terminals C1 to pass through the common platform CP1. In FIG. IF, the contacts BC1 and BC2 and the base terminal B1 are electrically connected, the contacts CC1 and CC2 and the collector terminal C1 are electrically connected, and such electrical connections are not limited to the exemplary plugs as illustrated in the figures. It is understood that the electrical connection may be established through one or more vertically extending conductive vias or metallic through vias for establishing shorter paths of electrical connection, and metallization patterns including traces/lines in the interconnect structure may be incorporated.

Through such decentralization arrangement, the non-peripheral or inner portion of the bonding plane BP1 of the diced unit becomes the open area, which allows further peripheral connection (within the peripheral region and/or adjacent to the corners of the diced unit) between the contacts EC2 of the emitter terminals E1 and the bonding pads in the passive device wafer. Through such peripheral/decentralization arrangement, a spared open inner region in the passive device portion of the diced unit is reserved for the layout of the passive devices in the passive device wafer and/or for other auxiliary circuits and matching networks, so that the layout design flexibility is extensively improved. Such flexibility significantly progresses the possibly complicated layout work of passive device wafer. Also, the disposition of the common platform excels in controlling thermal runaway issues, significantly improving the device's thermal management capabilities through optimized heat dissipation structures, thereby enhancing overall MMIC reliability.

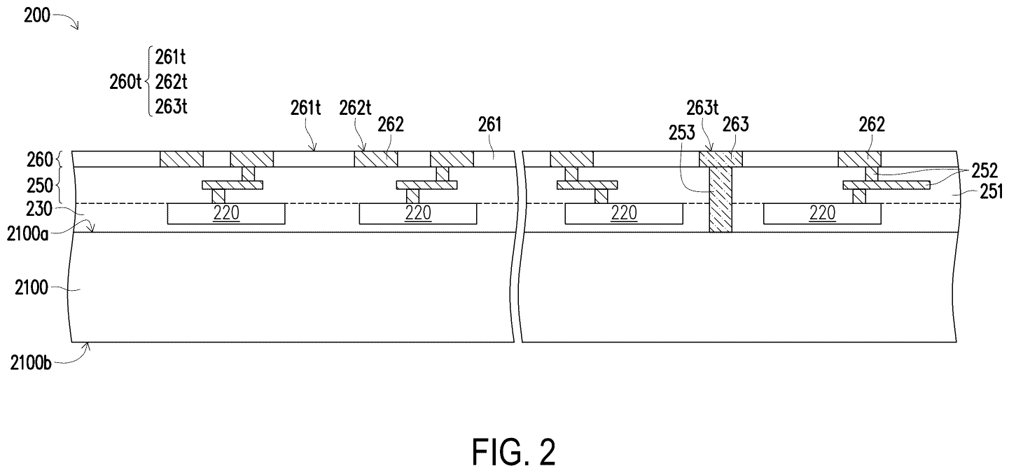

FIG. 2 is a schematic cross-sectional view illustrating a passive device wafer 200, according to some embodiments. Referring to FIG. 2, a passive device wafer 200 may include a second substrate 2100 including a first side (or a frontside) 2100a and a second side (or a backside) 2100b opposite to the first side 2100a. The second substrate 2100 may have one or more substrate material(s) such as glass, silicon, sapphire, compound semiconductor, semiconductor-on-insulator (SOI), a combination thereof, or other suitable substrate material(s) based on the semiconductor processing parameters for the structures formed thereon. In some embodiments, the material of the second substrate 2100 is different from the material of the first substrate 1100 described in FIG. 1A. For example, the first substrate 1100 is made of the substrate material(s) suitable for epitaxially growing, while the material(s) of the second substrate 2100 may be selected from a group of candidate substrate materials including substrate materials of low dielectric loss or substrate materials capable of withstanding high temperatures, depending on the type(s) of the passive devices to be formed. For example, the material of the first substrate 1100 can withstand the process temperatures less than 300° C., while the material of the second substrate 2100 can withstand the process temperatures higher than 300° C. or even up to 400° C. or 450° C. The material(s) of the second substrate 2100 may be independently chosen to suitably meet the performance requirements of the device(s) or element(s) formed therein or thereon, instead of compromising for accommodating the processing requirements for other device(s) formed in the first substrate 1100.

In alternative embodiments, the first substrate 1100 and the second substrate 2100 include substantially the same or similar substrate material(s).

With continued reference to FIG. 2, the passive device wafer 200 may include passive devices 220 formed over the first side 2100a of the second substrate 2100. The passive devices 220 may be or include inductors (e.g., planar spiral inductors, solenoidal inductors, or the like), capacitors (e.g., metal-insulator-metal (MIM) capacitors or the like), resistors, the like, a combination thereof, etc. The passive devices 220 may be used in various combinations for the application of interconnecting, filtering, impedance matching, termination, decoupling, the like, a combination thereof, etc. In some embodiments, the passive devices 220 are disposed side-by-side over the second substrate 2100. It should be noted that the arrangement of the passive devices 220 shown in FIG. 2 is merely an example, and the passive devices 220 may have a different arrangement than shown. For example, one of the passive devices 220 (e.g., implemented as a solenoidal inductor) is disposed over the other one of the passive devices 220 (e.g., implemented as a capacitor) along the thickness direction of the passive device wafer 200, where the axis of the solenoidal inductor is parallel to the first side 2100a of the second substrate 2100. In such configuration, the magnetic field of the solenoidal inductor may be concentrated and uniform inside the solenoid inductor and may be weaker outside the solenoid inductor, leading to less interference or coupling between the solenoid inductor and devices that are placed above or underneath the solenoid inductor. The inductance and the quality factor of the solenoid inductor may be more controllable and predictable. This is beneficial for circuit designs.

The materials for the passive devices 220 may be selected for the reduction of the size of the passive devices 220. In some embodiments, the dielectric film (not individually shown) in the passive devices 220 (e.g., the capacitors) may be or include one or more high dielectric constant (high-k) polymeric material(s) or other suitable dielectric material(s) which may increase the capacitance density and reduce the dimension of the capacitors. In some embodiments, one or more high resistivity material(s) may be used to form the passive devices 220 (e.g., the resistors). The size of the passive devices 220 (e.g., implemented as the resistors) may be reduced by performing one or more surface polishing processes on the second substrate 2100 and/or the dielectric layer formed thereon. For example, improved accuracy in overlaying the photomask (not shown) and the passive device wafer 200 is achieved by providing flatter surface to be patterned. The flatter the surface, the narrower the resistor's width may be achieved. Since the active device wafer 100 and the passive device wafer 200 are separately fabricated, the selection of the materials and the designs for the passive devices 220 may be more flexible as the concerns of certain processing on the active devices are no longer a process limitation. One of the advantages of separately fabricating the passive device wafer 200 may include that one or more processes under higher process temperature may be performed on the second substrate 2100 and through which the passive devices 220 with improved performance and/or reliability may be obtained.

It is understood that the passive device wafer 200 is a wafer structure comprised of multiple diced units or die units, which will be obtained after singulation performed upon the bonded structure of the passive device wafer 200 with the active device wafer 100.

In some embodiments, the passive device wafer 200 includes passive devices 220 embedded within at least one dielectric layer 230. The material of the dielectric layer 230 may be different from the material of the dielectric layer 130 described in FIG. 1C. In some embodiments, the dielectric layer 230 includes one or more high-k polymeric material(s) or other suitable dielectric material(s) formed as multiple sub-layers or a single layer. For example, the material of the dielectric layer 230 can withstand higher process temperature than the material of the dielectric layer 130. In some embodiments, interconnects (not individually shown) are formed in the dielectric layer 230 to horizontally connect adjacent passive devices 220.

With continued reference to FIG. 2, the passive device wafer 200 may include an interconnect structure 250 overlying the dielectric layer 230 and electrically coupled to the passive devices 220. The interconnect structure 250 may include a dielectric layer 251 and routing layers 252 embedded in the dielectric layer 251, where the routing layers 252 are electrically coupled to the passive devices 220. The routing layers 252 may include conductive pads, conductive vias, conductive lines, a combination thereof, etc. The passive device wafer 200 may include a bonding structure 260 formed over the interconnect structure 250 and electrically coupled to the passive devices 220 through the interconnect structure 250. In some embodiments, the bonding structure 260 includes a bonding dielectric layer 261 and a plurality of bonding features 262 laterally covered by the bonding dielectric layer 261. The bonding dielectric layer 261 may have a material different from the dielectric layer(s) 251 and/or 230. The bonding dielectric layer 261 may include a same/similar material as the bonding dielectric layer 161 of the active device wafer 100 described in FIG. 1E. Alternatively, the bonding dielectric layers 261 may include different materials from the bonding dielectric layer 161. The bonding features 262 may include one or more conductive material(s) and may be in electrical contact with the RDLs 252. In some embodiments, a planarization process (e.g., fine CMP, grinding, etc.) is performed on the bonding structure 260, such that the top surfaces 262t of the bonding features 262 and the top surface 261t of the bonding dielectric layer 261 are substantially coplanar with each other. It is understood that for the “substantially coplanar” surfaces, certain minor height differences are acceptable within process variations and may be achieved through chemical mechanical polishing (CMP) to facilitate subsequent hybrid wafer bonding techniques. Additionally, in hybrid bonding, bonding features 262t and the bonding dielectric layer 261t may intentionally include slight height variations (e.g., a few nanometers) to facilitate effective bonding, while still maintaining an overall substantially coplanar surface from a macroscopic perspective. The top surfaces 262t of the bonding features 262 and the top surface 261t of the bonding dielectric layer 261 may be collectively viewed as a bonding surface 260t of the bonding structure 260 of the passive device wafer 200.

With continued reference to FIG. 2, the bonding structure 260 may include thermally conductive features 263 embedded and laterally covered by the bonding dielectric layer 261. In some embodiments, the thermally conductive feature(s) 263 may include the same conductive material(s) as the material of the bonding features 262. Alternatively, the thermally conductive feature(s) 263 may include one or more material(s) with higher thermal conductivity than the material(s) of the bonding features 262. The top surfaces 263t of the thermally conductive features 263 may be substantially coplanar with the top surfaces 262t of the bonding features 262 and may be included in the bonding surface 260t. In some embodiments, thermally conductive pillars 253 may be formed below the thermally conductive features 263 and pass through the dielectric layers 251 and 230. For example, at this stage, the thermally conductive pillar(s) 253 may reach the first side 2100a of the second substrate 2100.

Still referring to FIG. 2, the passive device wafer 200 may then be prepared for the subsequently-performed bonding process (see FIG. 3A). The passive device wafer 200 may be composed of the second substrate 2100, the passive devices 220 formed over the second substrate 2100, the dielectric layer 230 embedding the passive devices 220 therein, the interconnect structure 250 overlying the dielectric layer 230 and the passive devices 220, and the bonding structure 260 overlying the interconnect structure 250. Since the second substrate 2100 does not undergo any epitaxial process, the passive device wafer 200 may be free of epitaxial layers formed therein. The passive device wafer 200 may be free of active devices (e.g., transistors, diodes, etc.). The passive devices 220 and the conductive features (e.g., 252 and 262) coupled thereto may not be formed as functional circuits/signal processing circuits (e.g., power amplifiers, low noise amplifiers, mixers, etc. for a RF application) at this stage. The passive device wafer 200 may be considered as a WIP unit, which is an essential part for forming the functional circuits/signal processing circuits.

FIGS. 3A-3G are schematic cross-sectional views illustrating a manufacturing method of an electronic device with a frontside to frontside configuration, according to some embodiments. Referring to FIG. 3A and with reference to FIGS. 1E and 2, the passive device wafer 200 may be stacked upon and bonded to the active device wafer 100. For simplification, the interconnect structure 150 within the active device wafer 100 in the following figures will be simplified by omitting certain elements and sub-structures with only the conductive layer 145 shown as the representative element embedded in the dielectric layer. Referring to FIG. 3A, the passive devices 220 in the passive device wafer 200 are stacked on and stacked over the active devices 120 in the active device wafer 100, so that the locations of the stacked passive devices 220 and the active devices 120 along the thickness direction (vertical direction in FIG. 3A) are overlapped. For example, the bonding structure 260 of the passive device wafer 200 is bonded to the bonding structure 160 of the active device wafer 100. In some embodiments, the bonding dielectric layer 261 of the bonding structure 260 is fused to the bonding dielectric layer 161 of the bonding structure 160. In some embodiments, each of the bonding features 262 of the bonding structure 260 is bonded to one of the bonding features 162 of the bonding structure 160. For example, the metals in the bonding features 262 and 162 contact and then diffuse each other to form metal-to-metal bonds. In some embodiments, the thermally conductive features 263 in the bonding structure 260 are bonded to the thermally conductive features 163 in the bonding structure 160 in a same manner as the bonding of the bonding features 262 and 162.

In some embodiments where the bonding surfaces (160t and 260t) have high planarity, the bonding interface 12F of the passive device wafer 200 and the active device wafer 100 is essentially flat and planar. Since the first side (frontside) 2100a of the passive device wafer 200 is closer to the first side (active side) 1100a of the active device wafer 100 than the second side (backside) 2100b of the passive device wafer 200, the first side (frontside) 2100a of the passive device wafer 200 can be construed as the frontside facing the frontside of the active device wafer 100. The configuration of the bonded structure in FIG. 3A may thus be viewed as the frontside to frontside configuration. After bonding the passive device wafer 200 to the active device wafer 100, the active devices 120 in the active device wafer 100 may be electrically coupled to the passive devices 220 in the passive device wafer 200 to form functional circuits/signal processing circuits (e.g., power amplifiers, low noise amplifiers, mixers, etc. for a RF application).

Herein, as mentioned previously in the peripheral/decentralization arrangement, the bonding of the bonding features 162/262 and the thermally conductive feature 263 between the active device wafer 100 and the passive device wafer 200 may resemble the connections between the bonding pads of the active device portion (corresponding to contacts EC2 on the bonding plane BP1) and the bonding pads of the passive device portion, which are confined within the peripheral portion or outer portions of the passive device portion. Through such arrangement, a spared open inner region in the passive device portion of the diced unit is reserved for the layout of the passive devices in the passive device wafer and/or for other auxiliary circuits and matching networks, so that the layout design flexibility is extensively improved.

Referring to FIG. 3B and FIG. 3A, a thinning process is optionally performed on the second side 2100b of the passive device wafer 200 to form a second substrate 210 with a thinned backside 210b. For example, the second substrate 210 has a thinned thickness 210H measured between the thinned backside 210b and the first side (frontside) 2100a. In some embodiments, the thinned thickness 210H is in a range of about 50 microns and about 250 microns. It should be noted that the value of the thinned thickness 210H may vary depending on design and product requirements. Alternatively, the thinning process is omitted as long as the thickness of the second substrate 2100 can meet the product or the following process requirements or the combination thereof. Next, portions of the second substrate 210 may be removed to form openings 210P in the second substrate 210, where the openings 210P exposes at least a portion of the passive devices 220. In some embodiments where the passive devices 220 are wrapped around by the dielectric layer 230, portions of the dielectric layer 230 are removed along with the portions of the second substrate 210 to form the openings 210P exposes at least a portion of the passive devices 220. In some embodiments, opening(s) 210P′ may be formed to expose at least a portion of the thermally conductive pillar(s) 253.

Referring to FIG. 3C and FIG. 3B, through substrate vias (TSVs) 271 may be formed in the openings 210P, and backside contact pads 272 may be formed on the TSVs 271. For example, one or more conductive material(s) may be formed in the openings 210P and on the thinned backside 210b of the second substrate 210 to form the TSVs 271 and the backside contact pads 272 connected to the TSVs 271. The TSVs 271 may be in physical and electrical contact with the passive devices 220. In some embodiments, thermally conductive TSV(s) 273 may be formed in the opening(s) 210P′ to be in thermal and physical contact with the thermally conductive pillar(s) 253. In some embodiments, thermally conductive pad(s) 274 may be formed on the thermally conductive TSV(s) 273. The thermally conductive TSV(s) 273 and the thermally conductive pad(s) 274 may include the same conductive material(s) as the TSVs 271 and the backside contact pads 272. Alternatively, the thermally conductive TSV(s) 273 and the thermally conductive pad(s) 274 include one or more material(s) having higher thermal conductivity than the materials of the TSVs 271 and the backside contact pads 272.

Referring to FIG. 3D and FIG. 3C, a protective layer 281 with openings 281P may be formed on the thinned backside 210b of the second substrate 210. For example, the openings 281P expose at least a portion of the backside contact pads 272 for further electrical connections. In some embodiments, the protective layer 281 includes openings 281P′ exposing at least a portion of the thermally conductive pad(s) 274 for further thermal dissipation. In some embodiments, an electronic device is provided as shown in FIG. 3D (or FIG. 3C), and the following steps described in FIGS. 3E-3G (or FIGS. 3D-3G) are optional.

Referring to FIG. 3E and FIG. 3D, conductive bumps 282 may be formed in the openings 281P and on the protective layer 281 to be in physical and electrical contact with the backside contact pads 272. The conductive bumps 282 may include one or more conductive material(s). In some embodiments, the conductive bumps 282 include a solder material and a reflow process is performed on the solder material to form a desired bump shape. In some embodiments, the respective conductive bump 282 includes a pillar portion and a cap portion overlying the pillar portion, where the pillar portion and the cap portion are made of different materials (e.g., copper and solder, or other suitable conductive materials). In some embodiments, thermally conductive bump(s) 283 may be formed in the openings 281P′ and on the protective layer 281 to be in physical and/or thermal and/or electrical contact with the thermally conductive pad(s) 274. The thermally conductive bump(s) 283 may include the same material(s) as the conductive bumps 282 or may include one or more material(s) with higher thermal conductivity than the material(s) of the conductive bumps 282.

Referring to FIGS. 3F-3G and FIG. 3E, a temporary carrier 51 may be bonded to the conductive bumps 282 and the thermally conductive bumps 283 through, e.g., a release layer 52. A thinning process may be performed on the second side 1100b of the first substrate 1100 to form the first substrate 110 with a thinned backside 110b. For example, the first substrate 110 has a thinned thickness 110H measured between the thinned backside 110b and the first side 1100a. In some embodiments, the thinned thickness 110H is in a range of about 25 microns and about 250 microns. It should be noted that the value of the thinned thickness 110H may vary depending on design and product requirements. After the thinning, the temporary carrier 51 may be de-bonded from the conductive bumps 282 and the thermally conductive bumps 283 by removing the release layer 52. Alternatively, the bonding of the temporary carrier 51 and the thinning process is omitted as long as the thickness of the first substrate 1100 can meet the product or the following process requirements or the combination thereof.

With continued reference to FIG. 3G, an electronic device ED1 may be provided. In some embodiments, the aforementioned steps are performed in a wafer level, and a singulation process is performed to separate the electronic devices ED1 from one another to form individual dies. In some embodiments, the aforementioned steps may involve wafer-to-wafer bonding, die-to-wafer bonding, die-to-die bonding, etc., and the electronic device ED1 may be a MMIC die, where operation frequency of the MMIC may range from hundreds of megahertz to tens of gigahertz. The respective electronic device ED1 may include an active device portion 10 and a passive device portion 20 stacked upon and bonded to the active device portion 10. The active device portion 10 and the passive device portion 20 may be bonded through hybrid bonding. In this manner, the electronic device ED1 may have lower signal transmission loss than the conventional microwave integrated circuit (MIC) die that uses bonding wires to make electrical connection between the active and passive devices.

The active device portion 10 includes active devices 120 and may be free of passive devices. The passive device portion 20 includes passive devices 220 and may be free of active devices. In some embodiments, each of the active devices 120 is electrically coupled to one of the passive devices 220 to form a functional circuit for analog signal processing. In some embodiments, each group (or a unit cell) of the active devices 120 is electrically coupled to one of the groups of the passive devices 220, where one or more of the active devices 120 may be included in a group, and one or more of the passive devices 220 may be included in a group.

With continued reference to FIG. 3G, during the operation of the electronic device ED1, as the heat may be mainly generated from the active devices 120, a thermal dissipation path 109 is provided in the electronic device EDI to efficiently transfer the heat from the active device portion 10 toward the passive device portion 20 and further transfer to the external component/environment. In some embodiments, the thermal dissipation path 109 in the electronic device ED1 not only is highly thermally conductive but also is electrically conductive. The thermal dissipation path 109 may include the thermally conductive bump(s) 283, the thermally conductive pad(s) 274, thermally conductive TSV(s) 273, the thermally conductive pillar(s) 253, the thermally conductive feature(s) (263 and 163), where the thermally conductive feature(s) 163 may be coupled to the conductive layer 145, and the conductive layer 145 may be coupled to the common emitter terminals of the active devices 120 (e.g., implemented as HBTs) or the source terminals of the active devices 120 (e.g., implemented as HEMTs) as mentioned in accompanying with FIG. 1E.

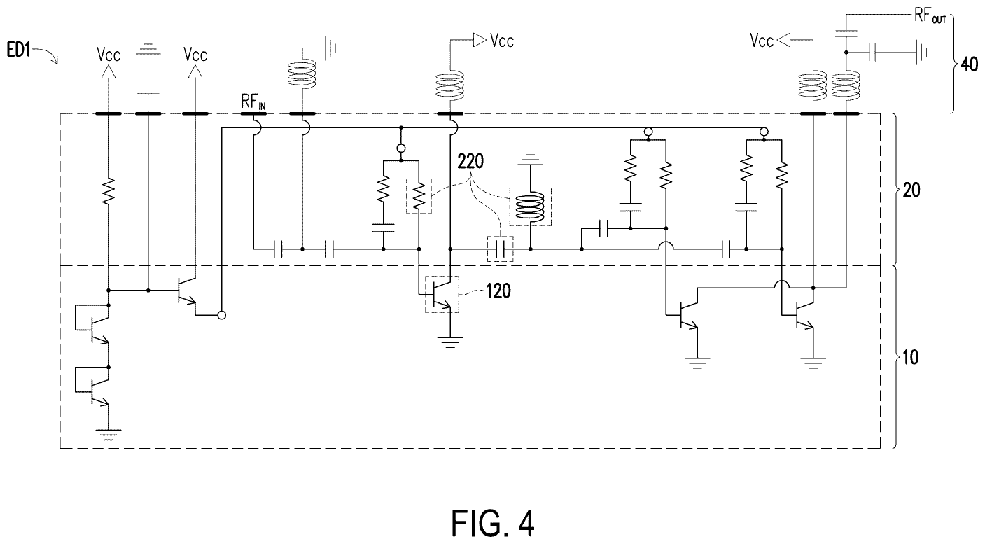

FIG. 4 is a circuit diagram of the electronic device of FIG. 3G, according to some embodiments. Referring to FIG. 4 and FIG. 3G, the electronic device ED1 may include the active device portion 10 and the passive device portion 20 stacked upon the active device portion 10. One or more external components 40 may be coupled to the electronic device ED1 through the passive device portion 20. In the RF application, the external components 40 may include discrete semiconductor devices, discrete passive devices, transmission lines, DC bias voltage terminals, etc. As mentioned in the preceding paragraphs, the active device portion 10 and the passive device portion 20 bonded together to form a functional circuit/signal processing circuit (e.g., power amplifiers, low noise amplifiers, mixers, etc. for a RF application). The active device portion 10 alone (or the passive device portion 20 alone) does not form a functional circuit/signal processing circuit. In the illustrated embodiment, the active devices (represented by transistors) are disposed within the active device portion 10 and the active device portion 10 is free of passive devices (e.g., resistors, capacitors, and inductors), while the passive devices (represented by resistors, capacitors, inductors) are disposed within the passive device portion 20 and the passive device portion 20 is free of active devices (e.g., transistors and diodes).

In alternative embodiments, the active device portion 10 includes the active devices 120 and a small number of passive devices (e.g., resistors, capacitors, and/or inductors) connected to the active devices 120 for certain purposes. For example, the active device portion 10 includes a few resistors (e.g., less than about 10% of the total area of passive devices) connected to some of the active devices, where the resistors are configured to control the current flow to these active devices connected to the resistors such that the thermal stability can be improved. In such cases, the combination of the active devices and the passive devices (e.g., the resistors) connected to the active devices in the active device portion 10 does not function as a signal processing circuit unless the active device portion 10 is bonded to the passive device portion 20.

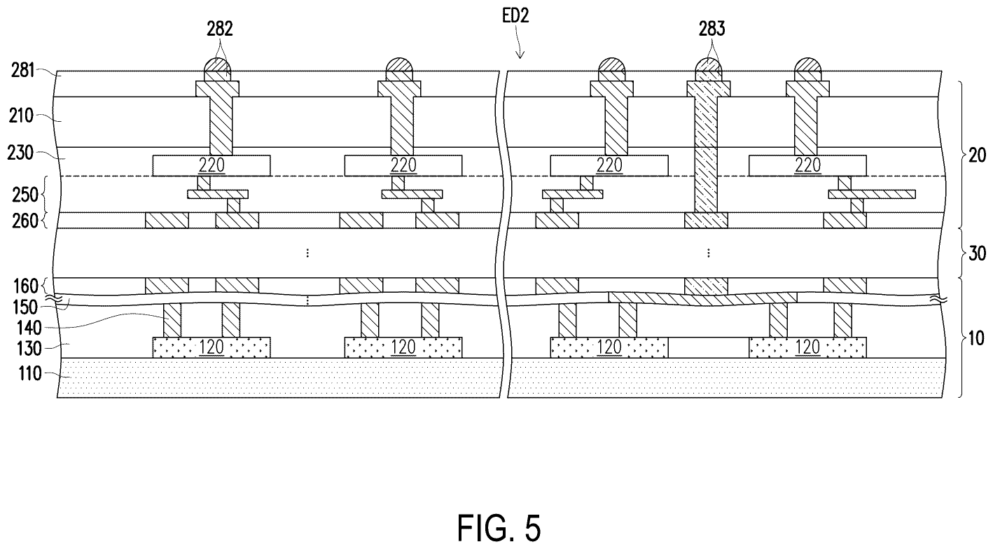

FIG. 5 is a schematic cross-sectional view of an electronic device, according to alternative embodiments. Referring to FIG. 5 and FIG. 3G, an electronic device ED2 shown in FIG. 5 may be similar to the electronic device ED1 described in FIG. 3G, except that electronic device ED2 further includes an additional portion 30 interposed between the active device portion 10 and the passive device portion 20. The additional portion 30 may be electrically and/or thermally coupled to the active device portion 10 and the passive device portion 20 through any suitable means (not individually shown). The additional portion 30 may be or include additional active device portion (e.g., formed from the active device wafer 100), additional passive device portion (e.g., formed from the passive device wafer 200), an interposer, a redistribution structure, the like, a combination thereof, etc.

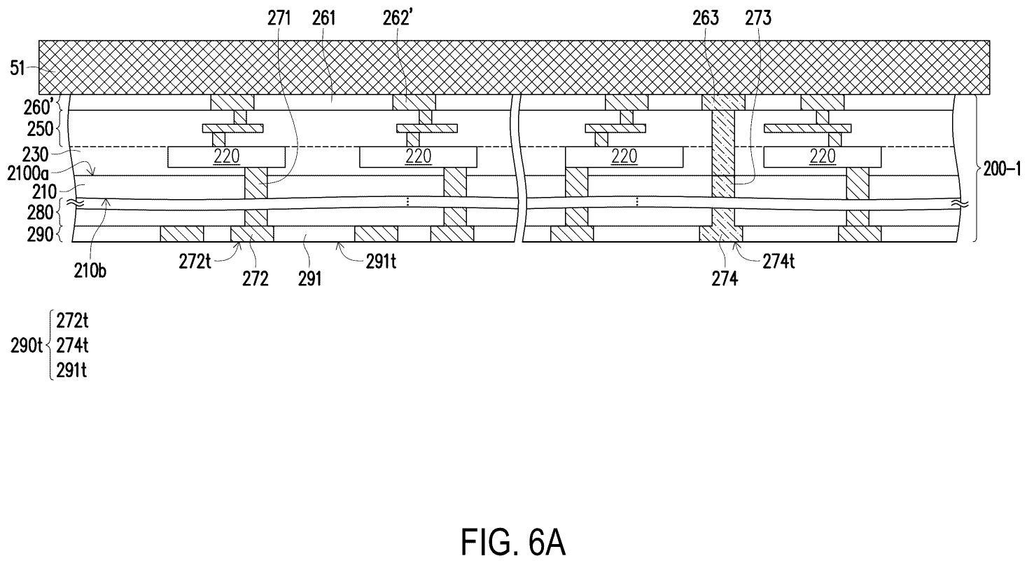

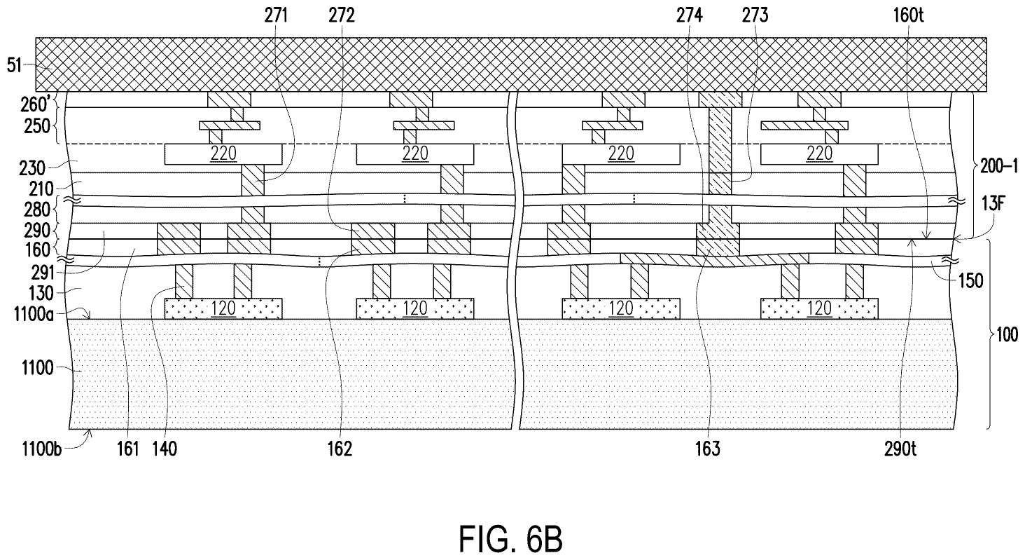

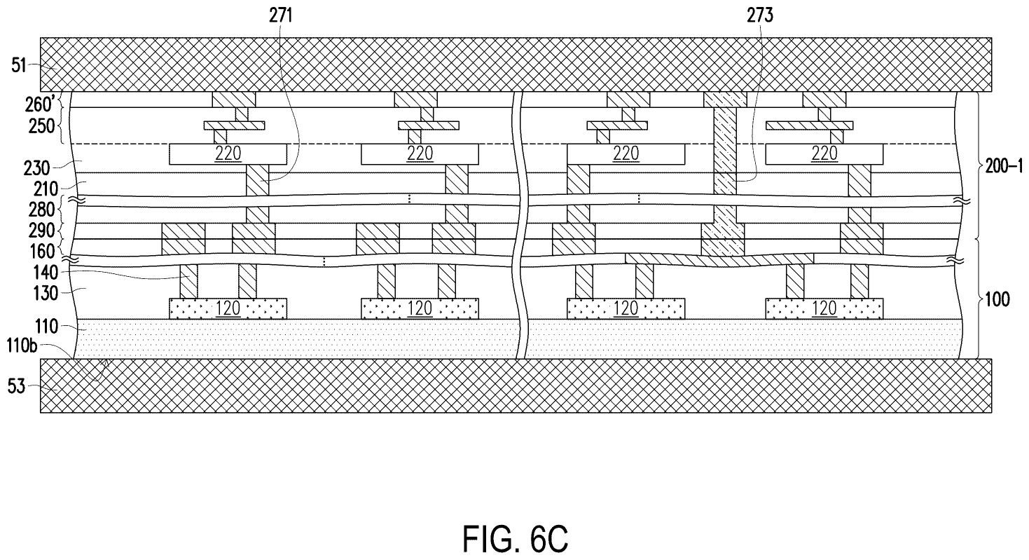

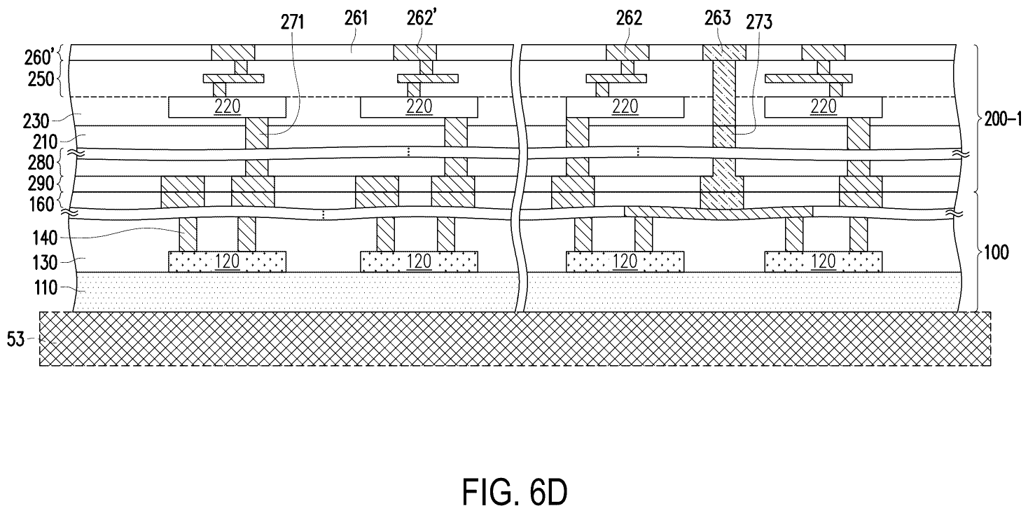

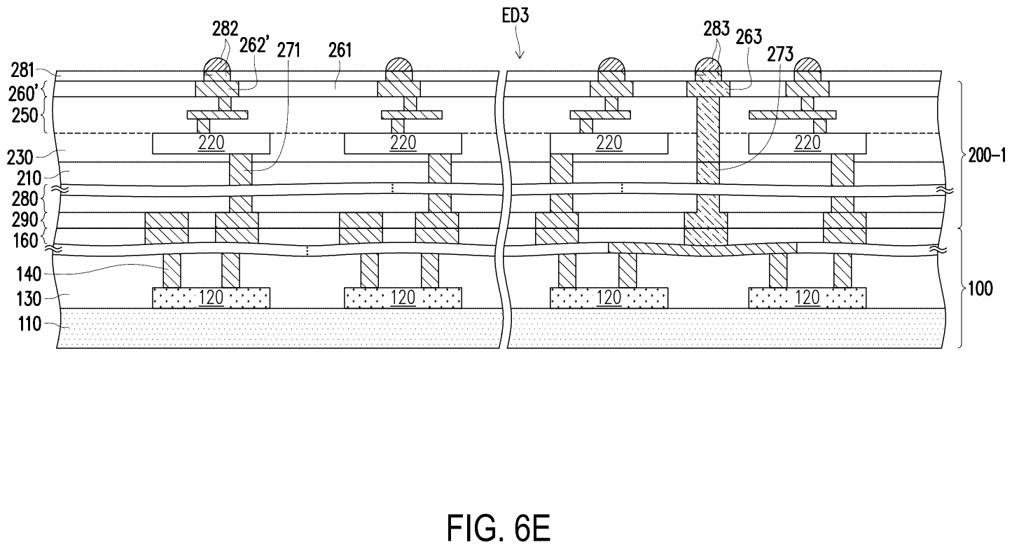

FIGS. 6A-6E are schematic cross-sectional views illustrating a manufacturing method of an electronic device with a frontside to backside configuration, according to some embodiments. The embodiments described in FIGS. 6A-6E are similar to the embodiments described in FIGS. 3A-3G, and thus like reference numerals indicate the like components. Referring to FIG. 6A, the passive device wafer 200-1 may be bonded to a first temporary carrier 51. The passive device wafer 200-1 may be similar to the passive device wafer 200 shown in FIG. 3C, and thus the detailed descriptions are not repeated for simplicity. Similar to the frontside bonding structure 260 of the passive device wafer 200, the connecting structure 260′ of the passive device wafer 200-1 does not function as a bonding structure and is adhered to the first temporary carrier 51 through, e.g., a release layer (not shown). In some embodiments, a bonding structure 290 is formed over the thinned backside 210b of the second substrate 210, and a backside interconnect structure 280 is disposed between the second substrate 210 and the bonding structure 290. For example, the bonding structure 260 formed over the first side 2100a of the second substrate 210 in the passive device wafer 200 is viewed as a frontside bonding structure, and the bonding structure 290 formed below the thinned backside 210b of the second substrate 210 opposite to the first side 2100a in the passive device wafer 200-1 is viewed as a backside bonding structure.

With continued reference to FIG. 6A, the bonding structure 290 may include a bonding dielectric layer 291 and the backside contact pads 272 laterally covered by the bonding dielectric layer 291, where the backside contact pads 272 may function as the bonding features 272 of the bonding structure 290. In some embodiments, a planarization process (e.g., fine CMP, grinding, etc.) is performed on the bonding structure 290 such that the lower surfaces 272t of the bonding features 272 and the lower surface 291t of the bonding dielectric layer 291 are substantially coplanar with each other, within process variations. The lower surfaces 272t of the bonding features 272 and the lower surface 291t of the bonding dielectric layer 291 may be collectively viewed as a bonding surface 290t of the bonding structure 290. The thermally conductive feature(s) 274 laterally covered by the bonding dielectric layer 291 may be included in the bonding structure 290. The lower surfaces 274t of the thermally conductive features 274 may be substantially coplanar with the lower surfaces 272t of the bonding features 272 and may be included in the bonding surface 290t. In some embodiments, the backside interconnect structure 280, similar to the interconnect structure 150, includes a dielectric layer and one or more metallization patterns (not individually shown) embedded in the dielectric layer. The metallization patterns of the backside interconnect structure 280 may electrically couple the TSVs 271 and the thermally conductive TSV(s) 273 to the backside contact pads 272 and the thermally conductive pad(s) 274, respectively. Alternatively, the backside interconnect structure 280 may be omitted.

Referring to FIG. 6B and FIG. 6A, the passive device wafer 200-1 carried by the first temporary carrier 51 may be aligned with the active device wafer 100 and then bonded to the active device wafer 100. The active device wafer 100 may be similar to the active device wafer 100 shown in FIG. 3C, and thus the detailed descriptions are not repeated for simplicity. In some embodiments, the bonding structure 290 of the passive device wafer 200-1 is bonded to the bonding structure 160 of the active device wafer 100. In some embodiments, the bonding dielectric layer 291 of the bonding structure 290 is fused to the bonding dielectric layer 161 of the bonding structure 160. Each of the bonding features 272 of the bonding structure 290 may be bonded to one of the bonding features 162 of the bonding structure 160 in a one-to-one fashion. For example, the metallic bonding features 272 and 162 contact and then metal-to-metal bonding is established between the bonded bonding features 272 and 162. The thermally conductive feature(s) 274 in the bonding structure 290 may be bonded to the thermally conductive feature(s) 163 in the bonding structure 160 in a same manner as the bonding of the bonding features 272 and 162.

In some embodiments, when the bonding surfaces (160t and 290t) have been planarized and have high planarity, the bonding interface 13F of the passive device wafer 200-1 and the active device wafer 100 is essentially flat and planar. Since the thinned backside 210b of the passive device wafer 200-1 is closer to the first side (frontside/active side) 1100a of the active device wafer 100 than the first side (frontside) 2100a of the passive device wafer 200-1, the thinned backside 210b of the passive device wafer 200-1 can be construed as the backside facing the frontside of the active device wafer 100. The configuration of the bonded structure in FIG. 6B may thus be viewed as the frontside to backside configuration. After bonding the passive device wafer 200-1 to the active device wafer 100, the active devices 120 in the active device wafer 100 may be electrically coupled to the passive devices 220 in the passive device wafer 200-1 to form functional circuits/signal processing circuits (e.g., power amplifiers, low noise amplifiers, mixers, etc. for a RF application).

Referring to FIGS. 6C-6D and FIG. 6B, a thinning process is optionally performed on the second side 1100b of the first substrate 1100 to form the first substrate 110 with the thinned backside 110b. The thinning of the active device wafer 100 may be similar to the process described in FIG. 3F, and thus the detailed descriptions are not repeated for simplicity. In some embodiments, after the thinning of the first substrate 1100, a second temporary carrier 53 is bonded to the thinned backside 110b of the first substrate 110 with (or without) a release layer interposed between the first substrate 110 and the second temporary carrier 53. The first temporary carrier 51 may then be de-bonded through any suitable removal techniques. After the de-bonding of the first temporary carrier 51, the connecting structure 260′ of the passive device wafer 200-1 may be revealed for further processing. In some embodiments, the bonding of the second temporary carrier 53 is optional, and an electronic device is provided as shown in FIG. 6D without the second temporary carrier 53. The following steps including the formation of conductive bumps and singulation described in FIG. 6E are optional.

Referring to FIG. 6E and FIG. 6D, the protective layer 281 (similar to the protective layer 281 described in FIG. 3D) is optionally formed on the connecting structure 260′. In some embodiments, the conductive bumps 282 (similar to the conductive bumps 282 described in FIG. 3E) are formed in the openings of the protective layer 281 to be in physical and electrical contact with the conductive features 262′ for further electrical connections. In some embodiments, the thermally conductive bumps 283 (similar to the thermally conductive bumps 283 described in FIG. 3E) are formed in the openings of the protective layer 281 to be in physical and/or thermal and/or electrical contact with the thermally conductive feature(s) 263 for further thermal dissipation. The formation of the conductive bumps 282 and/or the thermally conductive bumps 283 may be optional.

Still referring to FIG. 6E and with reference to FIG. 3G, an electronic device ED3 is obtained in FIG. 6E. In some embodiments, the aforementioned steps are performed in a wafer level, and a singulation process is performed to separate the electronic devices ED3 from one another and to form individual dies. In some embodiments, the aforementioned steps may involve wafer-to-wafer bonding, die-to-wafer bonding, die-to-die bonding, etc. The electronic device ED3 may be similar to the electronic device EDI described in FIG. 3G, except that the electronic device ED3 has a frontside to backside configuration as mentioned in accompanying with FIG. 6B. For example, the electronic device ED3 may be a MMIC die, where operation frequency of the MMIC may range from hundreds of megahertz to tens of gigahertz.

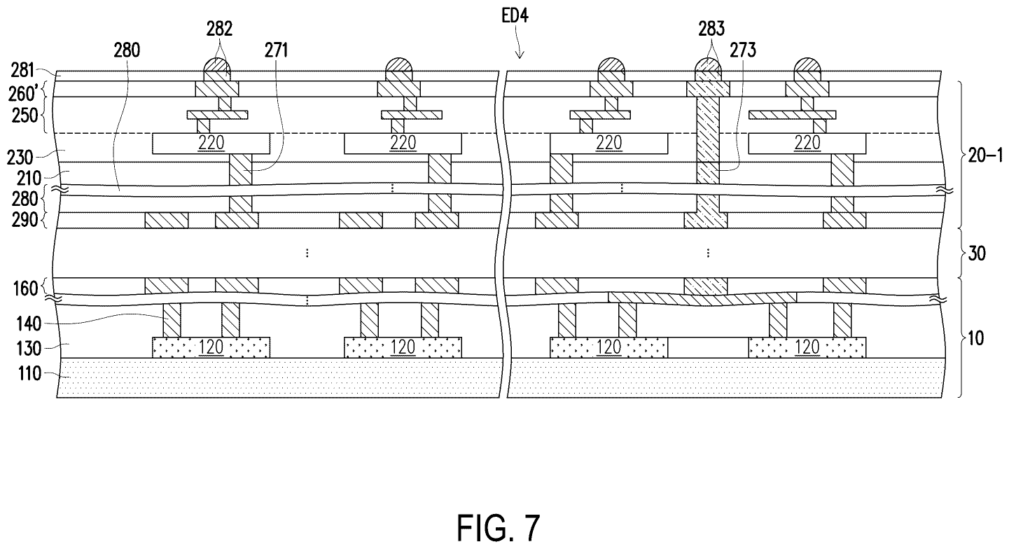

FIG. 7 is a schematic cross-sectional view of an electronic device, according to alternative embodiments. Referring to FIG. 7, FIG. 6E, and FIG. 5, an electronic device ED4 shown in FIG. 7 may be similar to the electronic device ED3 described in FIG. 6E, except that electronic device ED4 further includes an additional portion 30 interposed between the active device portion 10 and the passive device portion 20. The additional portion 30 may be electrically and/or thermally coupled to the active device portion 10 and the passive device portion 20 through any suitable means (not individually shown). The additional portion 30 may be similar to the additional portion 30 described in FIG. 5, and thus the detailed descriptions are not repeated for simplicity.

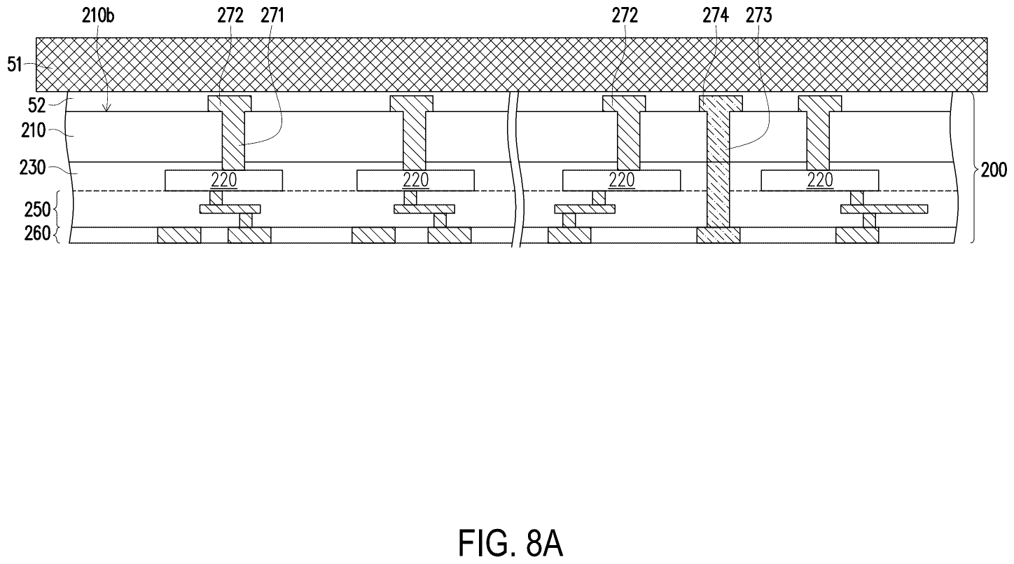

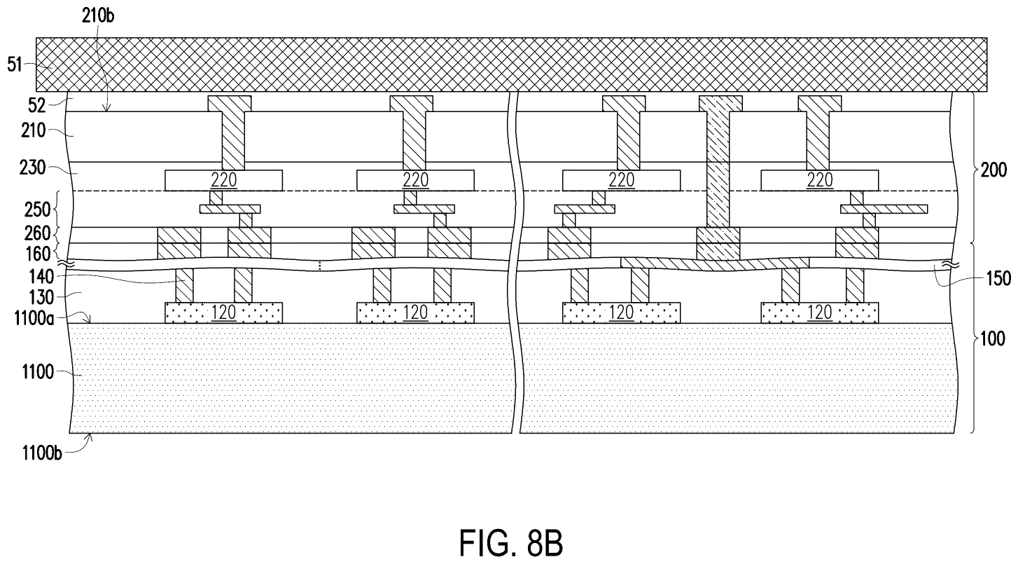

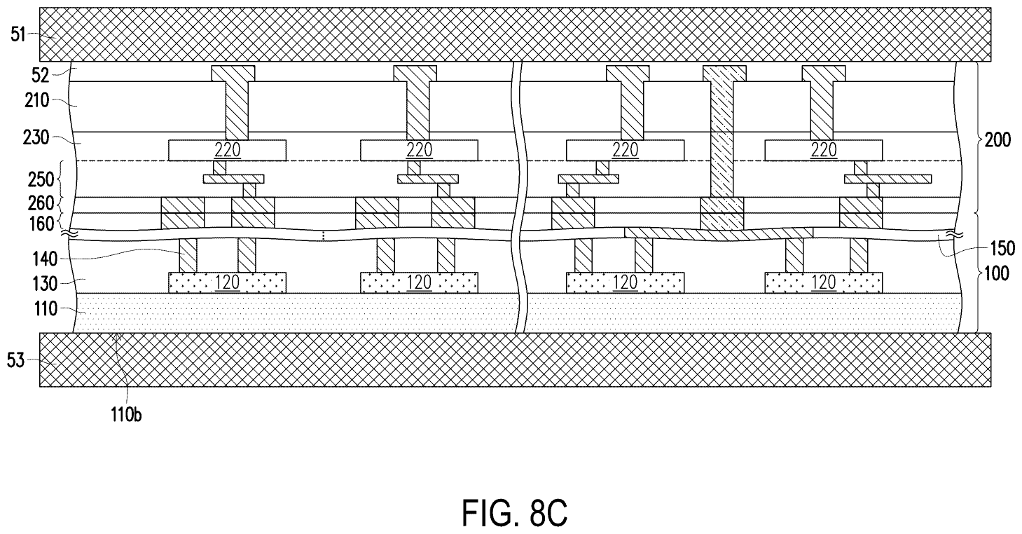

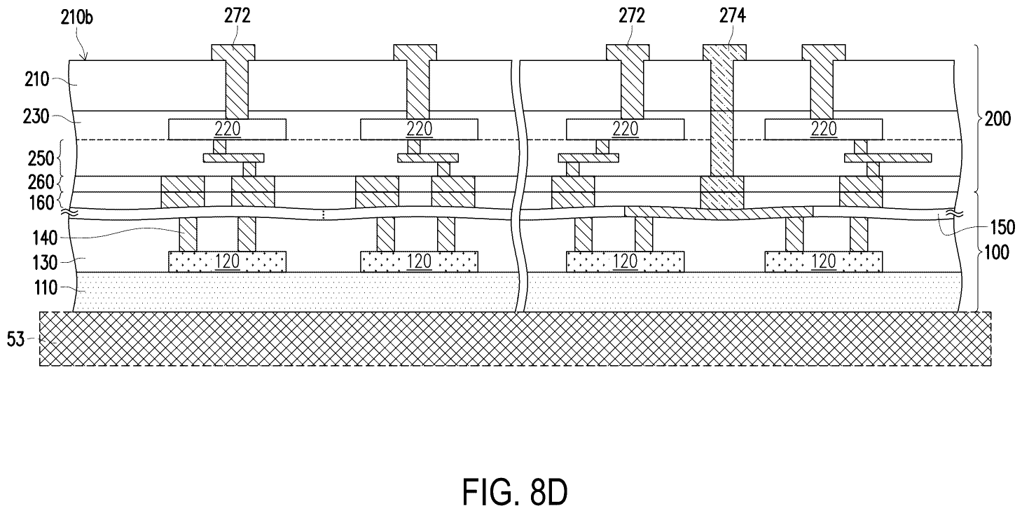

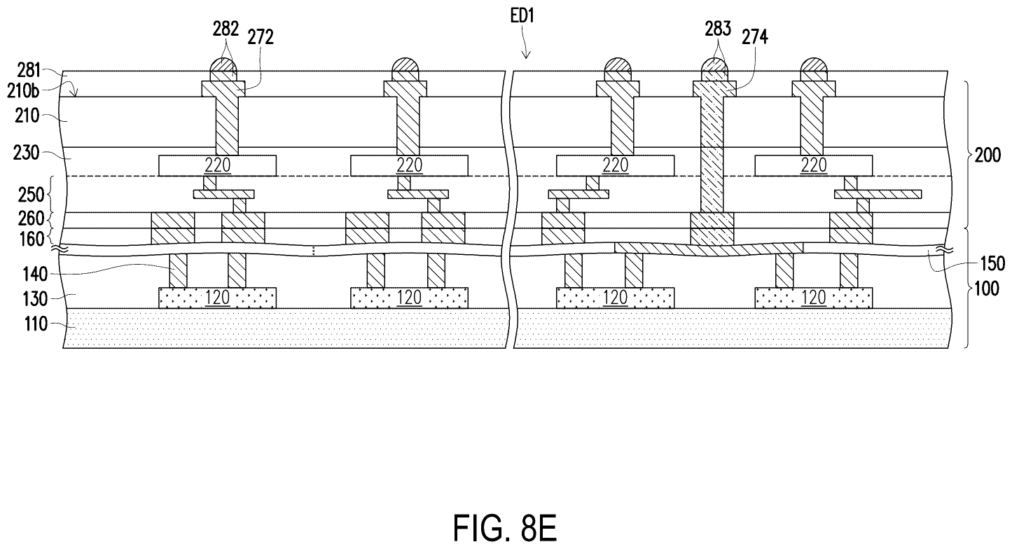

FIGS. 8A-8E are schematic cross-sectional views illustrating another manufacturing method of an electronic device with a frontside to frontside configuration, according to some embodiments. The embodiments described in FIGS. 8A-8E are similar to the embodiments described in FIGS. 3A-3G and FIGS. 6A-6E, and thus like reference numerals indicate the like components. Referring to FIG. 8A and FIGS. 3C and 6A, the passive device wafer 200 may be bonded to a first temporary carrier 51. The passive device wafer 200 may be similar to the passive device wafer 200 shown in FIG. 3C, and thus the detailed descriptions are not repeated for simplicity. In some embodiments, the thinned backside 210b of the second substrate 210 is bonded to the first temporary carrier 51 through, e.g., the release layer 52. The backside contact pads 272 and the thermally conductive pads 274 formed on the thinned backside 210b of the second substrate 210 may be covered by the release layer 52. By forming the TSVs 271, the backside contact pads 272, the thermally conductive TSVs 273, and the thermally conductive pads 274 formed in/on the second substrate 210 before the bonding process, the thermal budget of the manufacturing process for the electronic device may be reduced.

Referring to FIG. 8B and FIG. 8A, the passive device wafer 200 carried by the first temporary carrier 51 may be aligned with the active device wafer 100 and then bonded to the active device wafer 100. The active device wafer 100 may be similar to the active device wafer 100 shown in FIG. 3A, and thus the detailed descriptions are not repeated for simplicity. For example, the bonding structure 260 of the passive device wafer 200 is bonded to the bonding structure 160 of the active device wafer 100. The bonding may be similar to the process described in FIG. 3A, and thus the detailed descriptions are not repeated for simplicity.

Referring to FIGS. 8C-8D and FIG. 8B, a thinning process is optionally performed on the second side 1100b of the first substrate 1100 to form the first substrate 110 with the thinned backside 110b. The thinning of the active device wafer 100 may be similar to the process described in FIG. 3F, and thus the detailed descriptions are not repeated for simplicity. In some embodiments, after the thinning of the first substrate 1110, a second temporary carrier 53 is bonded to the thinned backside 110b of the first substrate 110 with (or without) a release layer interposed between the first substrate 110 and the second temporary carrier 53. The first temporary carrier 51 may then be de-bonded through any suitable removal techniques. After the de-bonding of the first temporary carrier 51, the thinned backside 210b of the second substrate 210, the backside contact pads 272, and the thermally conductive pads 274 of the passive device wafer 200 may be revealed for further processing. In some embodiments, the bonding of the second temporary carrier 53 is optional, and an electronic device is provided as shown in FIG. 8D without the second temporary carrier 53. The following steps including the formation of conductive bumps and singulation described in FIG. 8E are optional.

Referring to FIG. 8E and FIG. 8D, the protective layer 281 (similar to the protective layer 281 described in FIG. 3D) is optionally formed on the thinned backside 210b of the second substrate 210. In some embodiments, the conductive bumps 282 (similar to the conductive bumps 282 described in FIG. 3E) may be formed in/on the protective layer 281 to be in physical and electrical contact with the backside contact pads 272. The thermally conductive bumps 283 (similar to the thermally conductive bumps 283 described in FIG. 3E) may be formed in/on the protective layer 281 to be in physical and/or thermal and/or electrical contact with the thermally conductive pads 274. The formation of the conductive bumps 282 and the thermally conductive bumps 283 may be optional.

Still referring to FIG. 8E and with reference to FIG. 3G, an electronic device ED1 may be provided in FIG. 8E. In some embodiments, the aforementioned steps are performed in a wafer level, and a singulation process is performed to separate the electronic devices ED1 from one another and to form individual dies. In some embodiments, the aforementioned steps may involve wafer-to-wafer bonding, die-to-wafer bonding, die-to-die bonding, etc. The electronic device ED1 may be similar to the electronic device ED1 described in FIG. 3G, and thus the detailed descriptions are not repeated for simplicity.

Based on the above, the electronic device includes the active device portion and the passive device portion stacked upon and bonded to the active device portion. The active device portion and the passive device portion are separately fabricated and then bonded together to form a functional circuit/signal processing circuit (e.g., power amplifiers, low noise amplifiers, mixers, etc. for a RF application). The circuit may be a MMIC. The active device portion includes the active devices and the passive device portion includes the passive devices, and these devices in either portion do not possess the desired MMIC functionality unless the active device portion and the passive device portion bonded together. The MMIC may be utilized for the application in the RF and millimeter wave frequency band.

In addition, the thermal dissipation path is provided in the electronic device to transfer the heat from the active device portion toward the passive device portion and further dissipate to the external component/environment. As compared to the conventional MMIC utilizing through substrate vias that take a large area of the active device wafer for dissipating heat, the present disclosure adopts a new architecture for heat dissipation and distribution and thus less area is required for forming the active devices in the active device portion. Therefore, the amount of the active devices per unit area in the active device portion may increase as compared to the amount of the active devices per unit area in the conventional MMIC. Also, the density of the passive devices in the passive device portion may be increased as the matching concerns with the active devices are decentralized. Based on the optimized selection of the materials, the size of each of the active and passive devices in the electronic device may be reduced.

Moreover, by separately forming the active device portion from the active device wafer and forming the passive device portion from the passive device wafer individually and then bonding the active device portion and the passive device portion to form a 3DMMIC, the active device wafer and the passive device wafer can be fabricated individually and independently, eliminating the need to wait for the fabrication of one wafer to be completed before starting the other, thereby significantly reducing manufacturing time and increasing production throughput. Moreover, by separately processing the wafers, the selection of materials and the processing choices for either wafer may be more flexible. All of the manufacturing processes described in previous contexts may result in cost effective manufacturing.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A manufacturing method of an electronic device, comprising:
forming a first portion from a wafer, wherein forming the first portion comprises:
providing the first wafer having a first substrate;
forming a semiconductor epitaxial structure on the first substrate;
forming active devices from the semiconductor epitaxial structure grown on the first substrate; and
forming a first bonding structure over the first substrate and electrically coupled to the active devices;
forming a second portion from a second wafer, wherein the second portion is formed free of active devices, and forming the second portion comprises:
providing the second wafer having a second substrate;
forming passive devices over the second substrate; and
forming a second bonding structure electrically coupled to the passive devices; and
forming a signal processing circuit by bonding the first portion to the second portion, wherein the active devices are electrically coupled to the passive devices by bonding the first bonding structure to the second bonding structure to form the signal processing circuit.

2. The manufacturing method of claim 1, wherein before bonding the first portion to the second portion, each of the first portion and the second portion is formed as a work-in process unit which is unable to perform a function of signal processing.

3. The manufacturing method of claim 1, wherein the signal processing circuit is a microwave monolithic integrated circuit (MMIC).

4. The manufacturing method of claim 1, wherein forming the first portion comprises:
forming a dielectric layer over the first substrate to embed the active devices therein;
performing a smoothing process on a top surface of the dielectric layer;
forming the first bonding structure over the dielectric layer; and
performing a planarization process on a bonding surface of the first bonding structure before bonding the first portion to the second portion, wherein a surface roughness of the bonding surface of the first bonding structure is smaller than a surface roughness of the top surface of the dielectric layer.

5. The manufacturing method of claim 1, wherein the first wafer is provided with multiple diced units, and forming the first portion further comprises:
forming a common platform above the active device and between the active devices and the first bonding structure to be electrically coupled to a portion of the active devices, wherein the common platform is connected with the first bonding structure through conductive vias arranged in a peripheral region of each diced unit.

6. The manufacturing method of claim 1, wherein forming the first portion comprises:
forming the semiconductor epitaxial structure by epitaxially growing the semiconductor epitaxial structure on an active side of the first substrate; and
partially removing the semiconductor epitaxial structure to form the active devices, wherein a ratio of a total surface area of active areas of the active devices to a total surface area of the active side of the first substrate ranges from about 10% to about 90%.

7. The manufacturing method of claim 1, wherein forming the first bonding structure in the first portion comprises forming a first thermally conductive feature thermally coupled to at least a portion of the active devices,
forming the second portion comprises forming a second thermally conductive feature passing through the second substrate and the second bonding structure, and
the manufacturing method further comprises:
bonding the first thermally conductive feature to the second thermally conductive feature during bonding the first portion to the second portion.

8. The manufacturing method of claim 1, further comprising:
thinning at least one selected from the group of the first substrate and the second substrate after bonding the first portion to the second portion.

9. The manufacturing method of claim 1, further comprising forming through substrate vias in the second substrate to contact the passive devices between the second substrate and the second bonding structure.

10. The manufacturing method of claim 1, wherein the second bonding structure and the passive devices are formed at two opposing sides of the second substrate, and forming the second portion comprises:
forming through substrate vias in the second substrate to be in contact with the passive devices.

11. An electronic device, manufactured by the manufacturing method according to claim 1.

12. An electronic device, comprising:
a first portion, comprising:
a first substrate having a semiconductor epitaxial structure grown thereon;
active devices, formed from the semiconductor epitaxial structure on the first substrate; and
a first bonding structure, formed over the first substrate and electrically coupled to the active devices; and
a second portion, stacked upon the first portion and bonded to the first portion, the second portion being free of active devices and comprising:
a second substrate;
passive devices, disposed on the second substrate; and
a second bonding structure, electrically coupled to the passive devices,
wherein the first portion is obtained from a first semiconductor wafer, and the second portion is obtained from a second semiconductor wafer, and the active devices in the first portion and the passive devices in the second portion are electrically coupled through the bonded first and second bonding structures to form a signal processing circuit.

13. The electronic device of claim 12, wherein the signal processing circuit includes a microwave monolithic integrated circuit.

14. The electronic device of claim 12, wherein the first semiconductor wafer includes multiple diced units, the first portion includes a common platform located above the active device and between the active devices and the first bonding structure, the common platform that is electrically coupled with a portion of the active devices is connected with the first bonding structure through conductive vias arranged in a peripheral region of each diced unit.

15. The electronic device of claim 12, wherein the second portion is free of epitaxial layers.

16. An electronic device, comprising:
a signal processing circuit, including active devices in a first portion electrically coupling with passive devices in a second portion;
the first portion, comprising:
a first substrate having a semiconductor epitaxial layer on a front surface of the first substrate;
the active devices, made from the semiconductor epitaxial layer and disposed on the front surface of the first substrate; and
a first bonding structure, disposed over and electrically coupled to the active devices; and
the second portion, stacked upon and bonded to the first portion, the second portion being free of active devices and comprising:
a second substrate;
the passive devices, disposed on a frontside of the second substrate; and
a second bonding structure, electrically coupled to the passive devices and bonded to the first bonding structure to electrically connect the active devices and the passive devices to form the signal processing circuit.

17. The electronic device of claim 16, wherein the first portion further comprises:
a dielectric layer, overlying the first substrate and covering the active devices, wherein a top surface of the dielectric layer is rougher than a bonding surface of the first bonding structure of the first portion.

18. The electronic device of claim 16, wherein:
the first bonding structure of the first portion comprises a first bonding dielectric layer and first bonding features in the first bonding dielectric layer,
the second bonding structure of the second portion comprises a second bonding dielectric layer and second bonding features in the second bonding dielectric layer, and
the first bonding dielectric layer is fused to the second dielectric layer, and the first bonding features are bonded to the second bonding features.

19. The electronic device of claim 16, wherein the second portion is free of epitaxial layers.

20. The electronic device of claim 16, further comprising:
a thermal dissipation path, transferring heat generated from the active devices toward the second portion, the thermal dissipation path comprising:
a first thermally conductive feature, disposed in the first bonding structure of the first portion; and
a second thermally conductive feature, disposed in the second portion and bonded to the first thermally conductive feature, the second thermally conductive feature passing through the second bonding feature and the second substrate.
